(19) United States
(12) Patent Application Publication
(10) Pub. No.: US 2024/0389323 A1
(43) Pub. Date: Nov. 21, 2024

(54) SEMICONDUCTOR DEVICE AND METHOD OF MANUFACTURING THE SAME

(71) Applicant: SK hynix Inc., Icheon-si Gyeonggi-do (KR)

(72) Inventor: In Ku KANG, Icheon-si Gyeonggi-do (KR)

(73) Assignee: SK hynix Inc., Icheon-si Gyeonggi-do (KR)

(21) Appl. No.: 18/488,278

(22) Filed: Oct. 17, 2023

(30) Foreign Application Priority Data
May 16, 2023 (KR) 10-2023-0063037

(51) Int. Cl. H10B 43/27; H01L 21/28; H01L 29/423; H10B 43/10

(52) U.S. Cl. CPC H10B 43/27; H01L 29/40117; H01L 29/4234; H10B 43/10

(57) ABSTRACT

Provided herein may be a semiconductor device and a method of manufacturing the same. The semiconductor device may include a gate stacked structure including insulating layers and conductive layers that are alternatingly stacked, a hole extending in a vertical direction into the gate stacked structure, and including a first sidewall and a second sidewall facing each other, a first separation pattern and a second separation pattern that contact a boundary portion between the first sidewall and the second sidewall, the first and second separation patterns facing each other and extending in the vertical direction, a first plug pattern contacting the first sidewall and extending in the vertical direction, and a second plug pattern contacting the second sidewall and extending in the vertical direction.

### CROSS-REFERENCE TO RELATED APPLICATION

The present application claims priority under 35 U.S.C. § 119 (a) to Korean patent application number 10-2023-0063037 filed on May 16, 2023, in the Korean Intellectual Property Office, the entire disclosure of which is incorporated by reference herein.

### BACKGROUND

### 1. Technical Field

Various embodiments of the present disclosure generally relate to an electronic device, and more particularly to a semiconductor device and a method of manufacturing the semiconductor device.

### 2. Related Art

A nonvolatile memory device is a memory device that retains stored data even when the supply of power is interrupted. Recently, as a two-dimensional (2D) nonvolatile memory device in which memory cells are formed on a substrate in a single layer is reaching its physical scaling limit (e.g., degree of integration), a three-dimensional (3D) nonvolatile memory device including memory cells vertically stacked on a substrate has been proposed.

Such a 3D nonvolatile memory device may include interlayer insulating layers and gate electrodes that are alternatingly stacked on top of one another and channel layers penetrating the interlayer insulating layers and the gate electrodes, memory cells being stacked along the channel layers. To improve the operational reliability of such a 3D nonvolatile memory device, various structures and manufacturing methods have been developed.

### SUMMARY

An embodiment of the present disclosure may provide for a semiconductor device. The semiconductor device may include a gate stacked structure including insulating layers and conductive layers that are alternatingly stacked, a hole extending in a vertical direction into the gate stacked structure and including a first sidewall and a second sidewall facing each other, a first separation pattern and a second separation pattern that contact a boundary portion between the first sidewall and the second sidewall, the first and second separation patterns facing each other and extending in the vertical direction, a first plug pattern contacting the first sidewall and extending in the vertical direction, and a second plug pattern contacting the second sidewall and extending in the vertical direction.

An embodiment of the present disclosure may provide for a method of manufacturing a semiconductor device. The method may include forming a hole passing through at least a portion of a stacked structure, the stacked structure including first material layers and second material layers that are alternatingly stacked, forming a first separation pattern and a second separation pattern that contact a boundary between a first sidewall and a second sidewall of the hole, the first sidewall and the first separation pattern facing the second sidewall and the second separation pattern, respectively, and the first and second sidewalls and the first and second separation patterns extending in a vertical direction, forming a blocking insulating layer contacting the first sidewall and the second sidewall, forming a first charge trap layer and a second charge trap layer that contact an inner wall of the blocking insulating layer, the first and second charge trap layers being spaced apart from each other by the first separation pattern and the second separation pattern, forming a tunnel insulating layer contacting inner walls of the first charge trap layer and the second charge trap layer, and forming a first channel layer and a second channel layer that contact an inner wall of the tunnel insulating layer, the first and second channel layers being spaced apart from each other by the first separation pattern and the second separation pattern.

An embodiment of the present disclosure may provide for a method of manufacturing a semiconductor device. The method may include forming a hole passing through at least a portion of a stacked structure, the stacked structure including first material layers and second material layers that are alternatingly stacked, forming a first preliminary separation pattern and a second preliminary separation pattern that contact a boundary between a first sidewall and a second sidewall of the hole, the first sidewall and the first preliminary separation pattern facing the second sidewall and the second preliminary separation pattern, respectively, and the first and second sidewalls and the first and second preliminary separation patterns extending in a vertical direction, forming a first separation pattern and a second separation pattern from the first preliminary separation pattern and the second preliminary separation pattern, respectively, by performing an oxidization process, wherein the first separation pattern and the second separation pattern protrude toward a center of the hole, forming a blocking insulating layer contacting the first sidewall and the second sidewall, forming a first charge trap layer and a second charge trap layer that contact an inner wall of the blocking insulating layer, the first and second charge trap layers being spaced apart from each other by the first separation pattern and the second separation pattern, forming a tunnel insulating layer contacting inner walls of the first charge trap layer and the second charge trap layer, and forming a first channel layer and a second channel layer that contact an inner wall of the tunnel insulating layer, the first and second charge trap layers being spaced apart from each other by the first separation pattern and the second separation pattern.

### BRIEF DESCRIPTION OF THE DRAWINGS

FIGS. 1A, 1B, and 1C are a plan view and sectional views for explaining a semiconductor device according to an embodiment of the present disclosure.

FIGS. 2A, 2B, 2C, 3A, 3B, 3C, 4A, 4B, 4C, 5A, 5B, 5C, 6A, 6B, 6C, 7A, 7B, 7C, 8A, 8B, 8C, 9A, 9B, and 9C are plan views and sectional views for explaining a method of manufacturing a semiconductor device according to an embodiment of the present disclosure.

FIGS. 10A, 10B, and 10C are a plan view and sectional views for explaining a semiconductor device according to an embodiment of the present disclosure.

FIGS. 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, and 19C are plan views and sectional views for explaining a method of manufacturing a semiconductor device according to an embodiment of the present disclosure.

FIGS. 20A, 20B, 20C, 21A, 21B, 21C, 22A, 22B, 22C, 23A, 23B, 23C, 24A, 24B, 24C, 25A, 25B, 25C, 26A, 26B, 26C, 27A, 27B, 27C, 28A, 28B, 28C, 29A, 29B, and 29C are plan views and sectional views for explaining a method of manufacturing a semiconductor device according to an embodiment of the present disclosure.

FIG. 30 is a block diagram illustrating a memory system including a semiconductor device according to an embodiment of the present disclosure.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms and should not be construed as being limited to the embodiments described in the specification or application.

Various embodiments of the present disclosure will now be described in detail with reference to the accompanying drawings so that those skilled in the art can easily practice the technical spirit of the present disclosure.

Various embodiments of the present disclosure are directed to a semiconductor device including a vertical structure including a plurality of plug patterns and a method of manufacturing the semiconductor device.

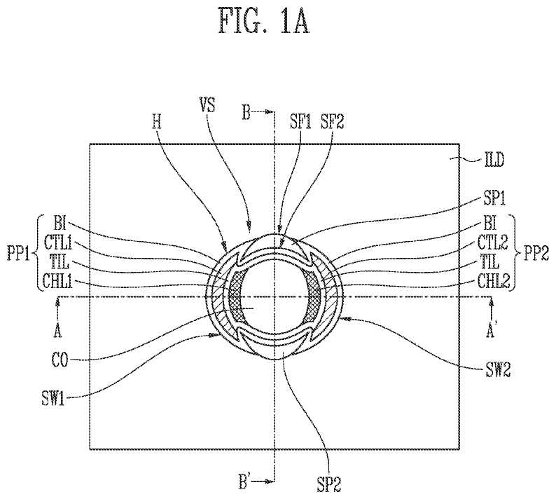

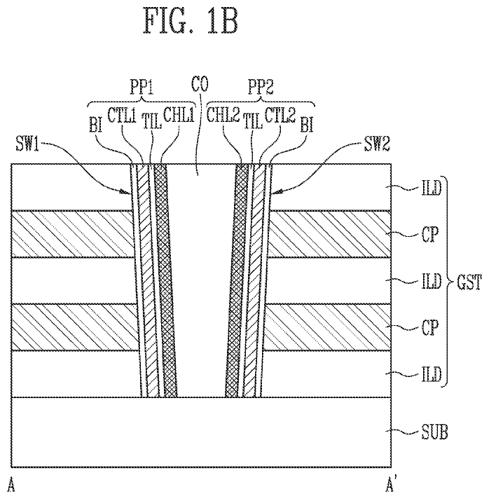

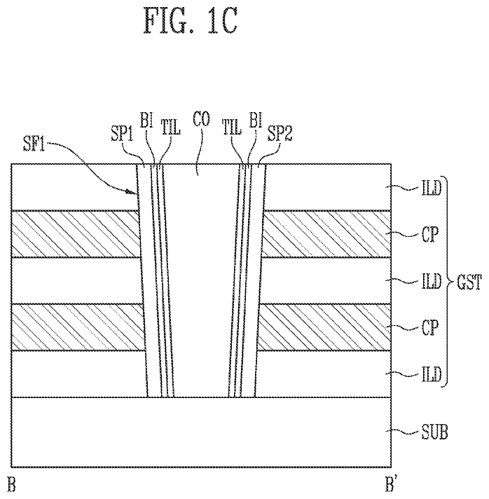

FIGS. 1A, 1B, and 1C are a plan view and sectional views for explaining a semiconductor device according to an embodiment of the present disclosure.

Referring to FIGS. 1A, 1B, and 1C, the semiconductor device may include a gate stacked structure GST and a vertical structure VS extending into the gate stacked structure GST in a vertical direction in relation to a substrate SUB.

The gate stacked structure GST may include conductive layers CP and interlayer insulating layers ILD, which are alternatingly stacked. The conductive layers CP may be gate electrodes of select transistors, memory cells, etc. The conductive layers CP may be select lines coupled to the select transistors and word lines coupled to the memory cells. The conductive layers CP may include a conductive material, such as polysilicon, tungsten, or metal. The interlayer insulating layers ILD may function to insulate the stacked conductive layers CP from each other. The interlayer insulating layers ILD may include an insulating material, such as oxide or nitride. Each of the interlayer insulating layers ILD may have a structure protruding toward the vertical structure VS in a horizontal direction.

The vertical structure VS may penetrate the gate stacked structure GST and may extend in the vertical direction in relation to the substrate SUB. That is, the vertical structure VS may extend in the stacking direction of the gate stacked structure GST. The stacking direction of the gate stacked structure GST may be defined as the direction in which the conductive layers CP and the interlayer insulating layers ILD that are included in the gate stacked structure GST are alternatingly stacked. The vertical structure VS may be disposed in a hole H that passes through the gate stacked structure GST.

The vertical structure VS may include a first plug pattern PP1, a second plug pattern PP2, a first separation pattern SP1, a second separation pattern SP2, and a core insulating layer CO. The first plug pattern PP1, the second plug pattern PP2, the first separation pattern SP1, the second separation pattern SP2, and the core insulating layer CO may extend in the vertical direction in relation to the substrate SUB.

The core insulating layer CO may be formed in the central region of the vertical structure VS and may include an insulating material, such as oxide.

The first plug pattern PP1 and the second plug pattern PP2 may have symmetrical structures along a first horizontal direction A-A′ of the hole H, which penetrates the gate stacked structure GST and extends in a vertical direction. The first horizontal direction A-A′ may be a direction that is parallel to the substrate SUB. That is, the first horizontal direction A-A′ may be a direction that is orthogonal to the vertical direction.

For example, the first plug pattern PP1 may include a blocking insulating layer BI formed along the first sidewall SW1 of the hole H, a first charge trap layer CTL1 contacting the inner wall of the blocking insulating layer BI, a tunnel insulating layer TIL contacting the inner wall of the first charge trap layer CTL1, and a first channel layer CHL1 contacting the inner wall of the tunnel insulating layer TIL. The first channel layer CHL1 may contact the sidewall of the core insulating layer CO, the tunnel insulating layer TIL may contact the outer wall of the first channel layer CHL1, the first charge trap layer CTL1 may contact the outer wall of the tunnel insulating layer TIL, and the blocking insulating layer BI may contact the outer wall of the first charge trap layer CTL1.

For example, the second plug pattern PP2 may include a blocking insulating layer BI formed along the second sidewall SW2 of the hole H facing the first sidewall SW1, a second charge trap layer CTL2 contacting the inner wall of the blocking insulating layer BI, a tunnel insulating layer TIL contacting the inner wall of the second charge trap layer CTL2, and a second channel layer CHL2 contacting the inner wall of the tunnel insulating layer TIL. The second channel layer CHL2 may contact the sidewall of the core insulating layer CO, the tunnel insulating layer TIL may contact the outer wall of the second channel layer CHL2, the second charge trap layer CTL2 may contact the outer wall of the tunnel insulating layer TIL, and the blocking insulating layer BI may contact the outer wall of the second charge trap layer CTL2.

The first and second channel layers CHL1 and CHL2 may be regions in which the channels of select transistors, memory cells, etc. are formed. Each of the first and second channel layers CHL1 and CHL2 may include a semiconductor material, such as silicon or germanium, or a nanostructure, such as nanodots, nanotubes, or graphene. The tunnel insulating layer TIL may be a layer in which charges are tunneled by F-N tunneling or like and may include an insulating material, such as oxide or nitride. Each of the first and second charge trap layers CTL1 and CTL2 may include a charge trapping material, nitride, a variable resistance material or a nanostructure, or a combination thereof. The blocking insulating layer BI may include a high-dielectric layer.

The first separation pattern SP1 and the second separation pattern SP2 may have symmetrical structures along the second horizontal direction B-B′ of the hole H. The second horizontal direction B-B′ may be a direction that is orthogonal to the first horizontal direction A-A′ and horizontal to the substrate SUB. The first separation pattern SP1 and the second separation pattern SP2 may extend in the vertical direction in relation to the substrate SUB, and a horizontal cross-section of each of the first and second separation patterns SP1 and SP2 may have a crescent shape. For example, the first sidewall SF1, which is the outer wall of each of the first separation pattern SP1 and the second separation pattern SP2, is a curved surface that is convex in relation to outside the hole H, and the second sidewall SF2, which is the inner wall of each of the first separation pattern SP1 and the second separation pattern SP2, may be a curved surface that is concave in relation to the center of the hole H. Each of the first separation pattern SP1 and the second separation pattern SP2 may be disposed to contact a boundary portion between the first sidewall SW1 and the second sidewall SW2 of the hole H.

Each of the first separation pattern SP1 and the second separation pattern SP2 may include an insulating material. For example, each of the first separation pattern SP1 and the second separation pattern SP2 may be formed of an oxide layer or a silicon oxide layer.

The blocking insulating layer BI of the first plug pattern PP1 and the second plug pattern PP2 may be formed along the sidewalls of the first separation pattern SP1 and the second separation pattern SP2. That is, the blocking insulating layer BI of the first plug pattern PP1 and the blocking insulating layer BI of the second plug pattern PP2 may be formed along the sidewalls of the first separation pattern SP1 and the second separation pattern SP2 and may be coupled to each other. Furthermore, the tunnel insulating layer TIL of the first plug pattern PP1 and the tunnel insulating layer TIL of the second plug pattern PP2 may be formed along the inner walls of the blocking insulating layers BI and may be coupled to each other.

The first charge trap layer CTL1 of the first plug pattern PP1 and the second charge trap layer CTL2 of the second plug pattern PP2 may be spaced apart from each other by the first separation pattern SP1 and the second separation pattern SP2. Also, the first channel layer CHL1 of the first plug pattern PP1 and the second channel layer CHL2 of the second plug pattern PP2 may be spaced apart from each other by the first separation pattern SP1 and the second separation pattern SP2.

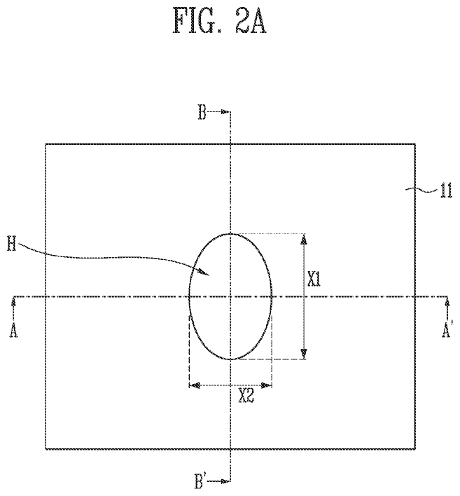

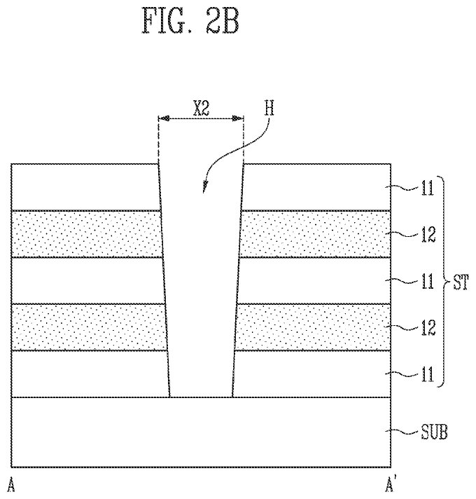

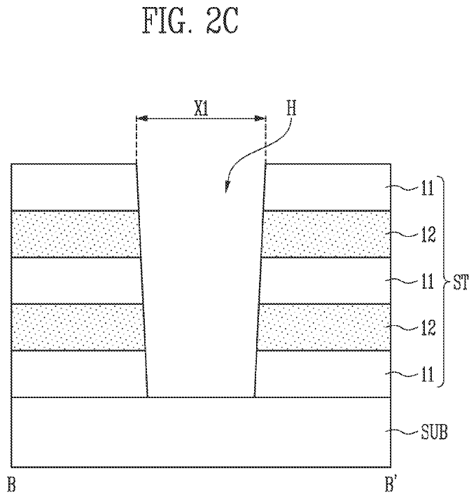

FIGS. 2A, 2B, 2C, 3A, 3B, 3C, 4A, 4B, 4C, 5A, 5B, 5C, 6A, 6B, 6C, 7A, 7B, 7C, 8A, 8B, 8C, 9A, 9B, and 9C are plan views and sectional views for explaining a method of manufacturing a semiconductor device according to an embodiment of the present disclosure.

Referring to FIGS. 2A, 2B, and 2C, a stacked structure ST may be formed on a substrate SUB. The stacked structure ST may include first material layers 11 and second material layers 12, which are alternatingly stacked. The first and second material layers 11 and 12 may be stacked in a vertical direction in relation to the substrate SUB. The first and second material layers 11 and 12 may be formed through a deposition process, such as chemical vapor deposition (CVD).

The first material layers 11 may include a material having an etch selectivity that is higher than that of the second material layers 12. In an example, each of the first material layers 11 may include an insulating material, such as oxide, and each of the second material layers 12 may include a sacrificial material, such as nitride. In an example, each of the first material layers 11 may include an insulating material, such as oxide, and each of the second material layers 12 may include a conductive material, such as polysilicon or tungsten.

Then, a hard mask pattern (not illustrated) may be formed on the stacked structure ST, and a hole H passing through at least a portion of the stacked structure ST may be formed by performing an etching process by using the hard mask pattern. The hole H may partially extend into the substrate SUB.

The hole H may be formed such that the width X2 thereof in a first horizontal direction A-A′ is narrower than the width X1 thereof in a second horizontal direction B-B′. For example, the cross-section of the hole H may have an elliptical shape.

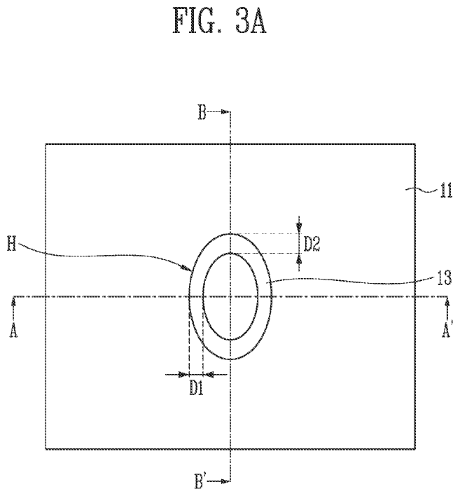

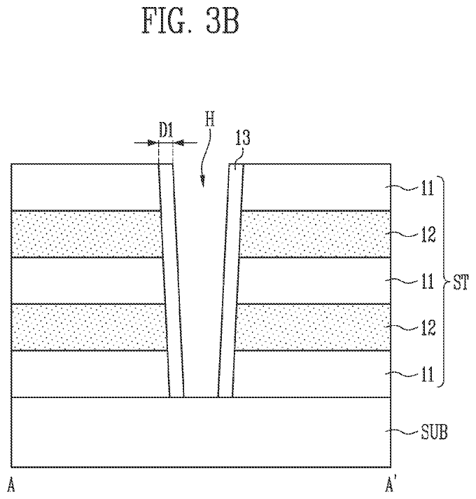

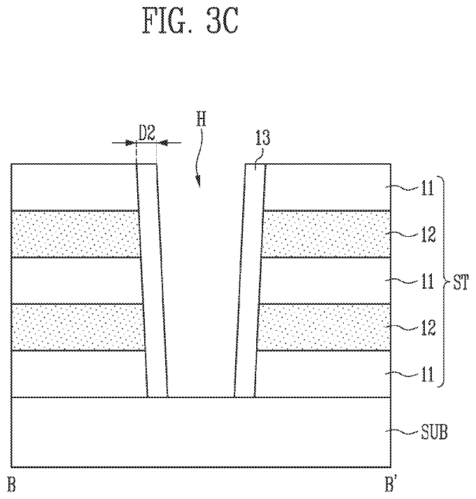

Referring to FIGS. 3A, 3B, and 3C, an insulating layer 13 may be formed along the sidewall of the hole H. The insulating layer 13 may be an oxide layer. The insulating layer 13 may include silicon oxide. The thickness D1 of the insulating layer 13 formed on the sidewall of the hole H in the first horizontal direction A-A′ may be formed to be different from the thickness D2 of the insulating layer 13 formed on the sidewall of the hole H in the second horizontal direction B-B′. The thickness D1 of the insulating layer 13 formed on the sidewall of the hole H in the first horizontal direction A-A′ may be less than the thickness D2 of the insulating layer 13 formed on the sidewall of the hole H in the second horizontal direction B-B′.

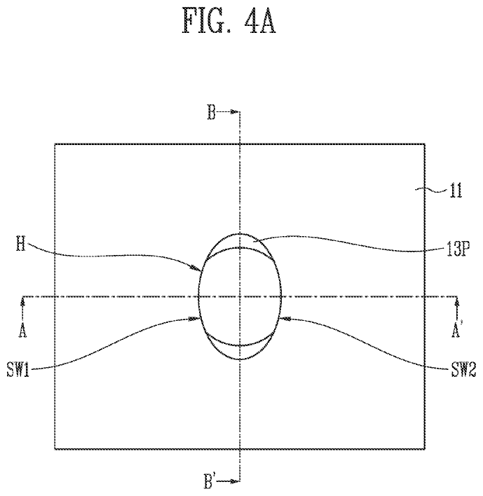

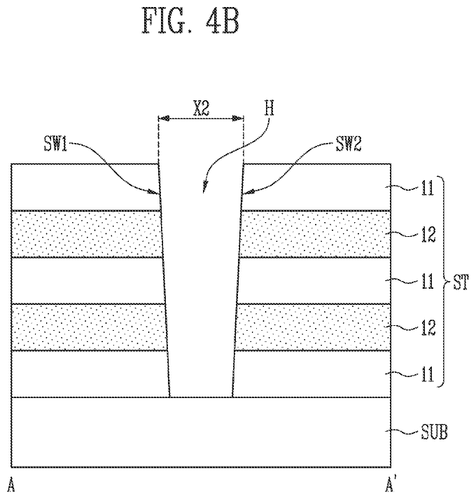

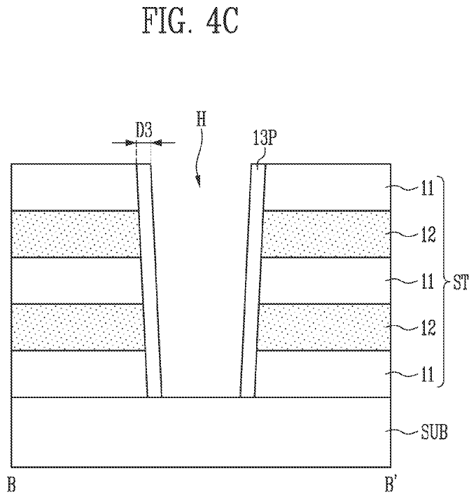

Referring to FIGS. 4A, 4B, and 4C, the insulating layer (e.g., 13 of FIGS. 3A, 3B, and 3C) may be etched to a certain thickness by performing an etching process and may then be partially removed. The etching process may be performed though an isotropic etching process. For example, a portion of the insulating layer 13 may be etched and removed such that the sidewall of the hole H in the first horizontal direction A-A′ is exposed. During the etching process, the thickness of the insulating layer 13 formed on the sidewall of the hole H in the first horizontal direction A-A′ may be less than that of the insulating layer 13 formed on the sidewall of the hole H in the second horizontal direction B-B′. Accordingly, even though the insulating layer 13 is etched such that the sidewall of the hole H in the first horizontal direction A-A′ is exposed, the insulating layer 13 may remain on the sidewall of the hole H in the second horizontal direction B-B′. Furthermore, the etching rate in the first horizontal direction A-A′ may be higher than that in the second horizontal direction B-B′ due to the differences between surface areas of the insulating layer 13 exposed to an etching agent and between surface angles thereof during the isotropic etching process. Therefore, separation patterns 13P may be formed on both sidewalls of the hole H in the second horizontal direction B-B′. A horizontal cross-section of each separation pattern 13P may have a crescent shape. Before the etching process is performed, the thickness D3 of the separation pattern 13P may be less than the thickness (e.g., D2 of FIG. 3C) of the insulating layer 13 formed on the sidewall of the hole H in the second horizontal direction B-B′.

The sidewall of the hole H may be divided into a first sidewall SW1 and a second sidewall SW2 based on the separation patterns 13P. For example, both sides of the hole H in the first horizontal direction A-A′ may be divided into the first sidewall SW1 and the second sidewall SW2.

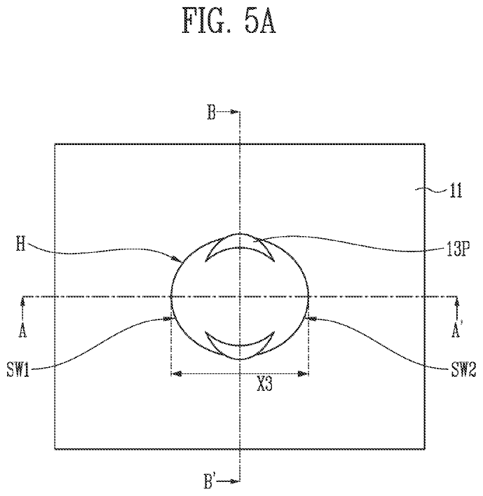

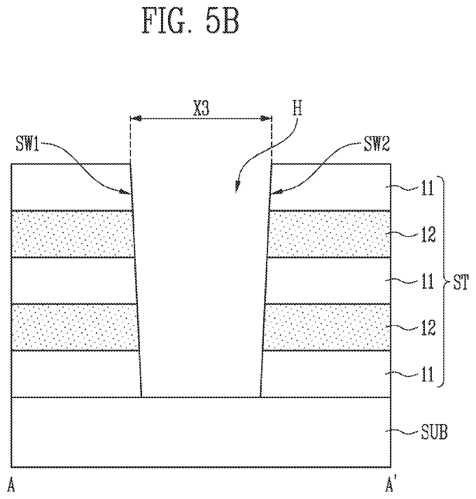

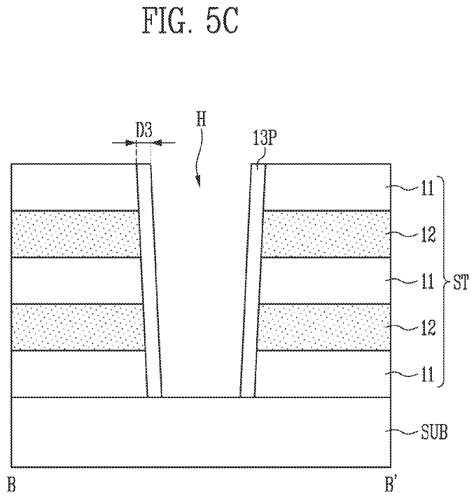

Referring to FIGS. 5A, 5B, and 5C, an etching process may be performed to expand the hole H. For example, the width X3 of the hole H in the first horizontal direction A-A′ may be extended by etching the first sidewall SW1 and the second sidewall SW2 of the hole H, which are exposed.

Both ends of each separation pattern 13P may protrude into the hole H through the etching process.

During the etching process, the sidewall of the hole H in the second horizontal direction B-B′ may be prevented from being etched by the separation patterns 13P, and thus, the width of the hole H in the second horizontal direction B-B′ might not extend.

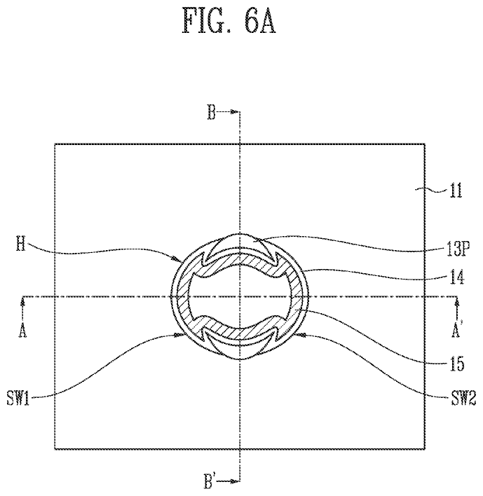

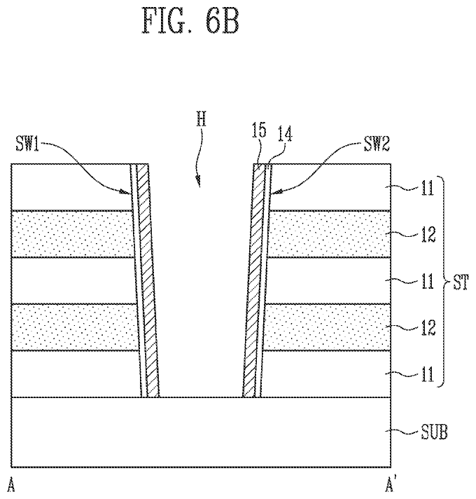

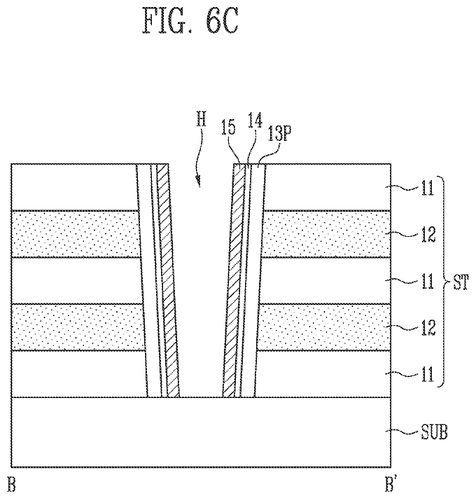

Referring to FIGS. 6A, 6B, and 6C, a blocking insulating layer 14 may be formed along the exposed first and second sidewalls SW1 and SW2 of the hole H and the exposed sidewalls of the separation patterns 13P. The blocking insulating layer 14 may be a high-dielectric layer.

Thereafter, a charge trap layer 15 may be formed along the inner wall of the blocking insulating layer 14. The data trap layer 15 may include a charge trapping material, nitride, a variable resistance material, or a nanostructure, or a combination thereof.

The blocking insulating layer 14 and the charge trap layer 15 that are sequentially formed along the sidewalls of the separation patterns 13P may protrude into the hole.

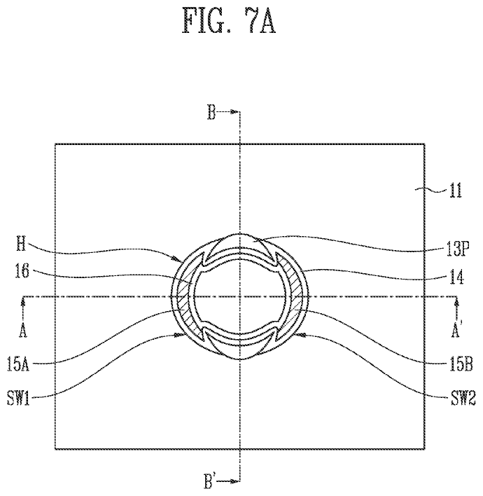

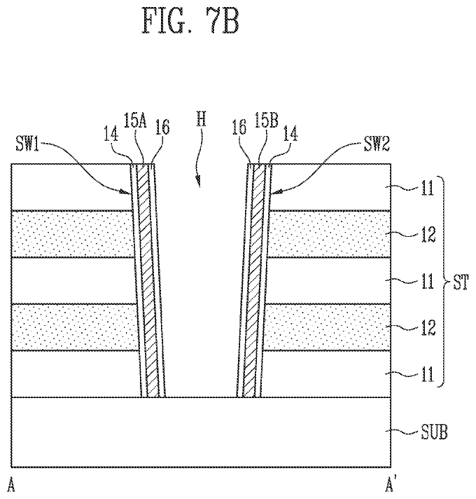

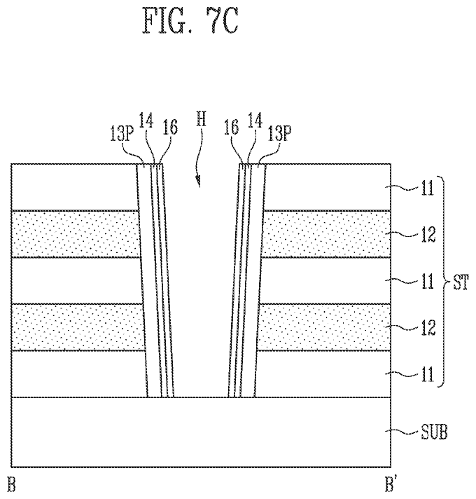

Referring to FIGS. 7A, 7B, and 7C, a first charge trap layer 15A and a second charge trap layer 15B may be formed by partially removing the charge trap layer (e.g., 15 of FIG. 6A). For example, the charge trap layer (e.g., 15 of FIG. 6A) adjacent to the separation patterns 13P may be removed by performing an etching process. That is, the charge trap layer (e.g., 15 of FIG. 6A) protruding into the hole may be etched and removed, and thus, the first charge trap layer 15A and the second charge trap layer 15B spaced apart from each other may be formed. The blocking insulating layer 14 may be exposed where a portion of the charge trap layer (e.g., 15 of FIG. 6A) has been removed.

Thereafter, a tunnel insulating layer 16 may be formed along the sidewalls of the first charge trap layer 15A and the second charge trap layer 15B. The tunnel insulating layer 16 may be a layer in which charges are tunneled by F-N tunneling or like and may include an insulating material, such as oxide or nitride. The tunnel insulating layer 16 may be formed to cover the exposed sidewall of the blocking insulating layer 14.

The tunnel insulating layer 16 adjacent to the separation patterns 13P may protrude into the hole H.

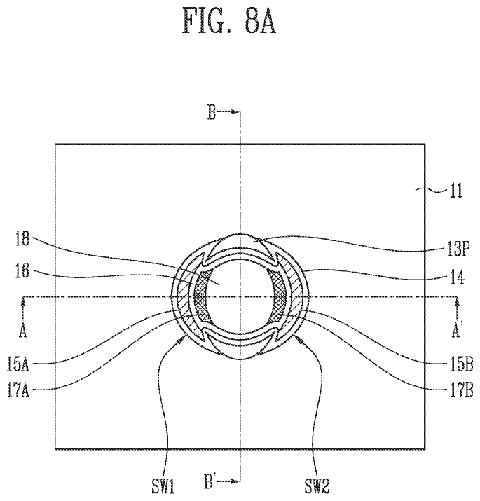

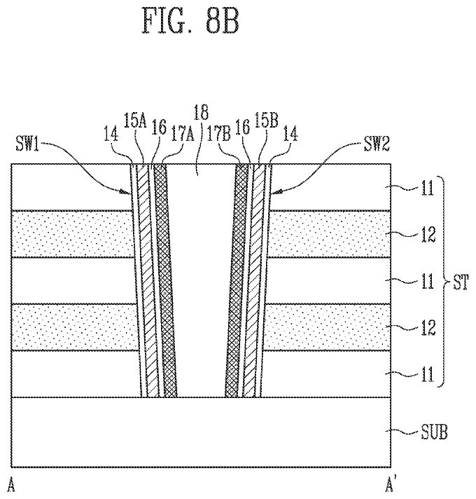

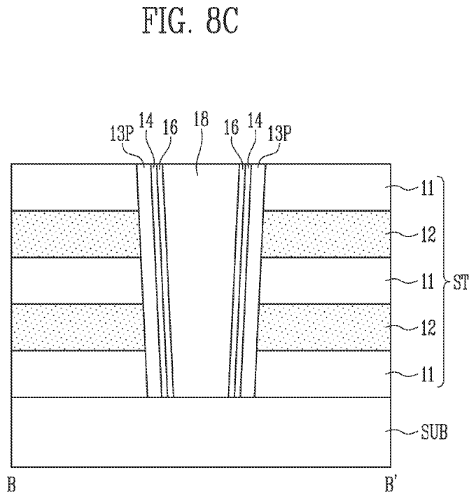

Referring to FIGS. 8A, 8B, and 8C, first and second channel layers 17A and 17B are respectively formed on both sidewalls of the tunnel insulating layer 16 in the first horizontal direction A-A′. For example, each of the first and second channel layers 17A and 17B may include a semiconductor material, such as silicon or germanium, an oxide semiconductor material, such as ZnO, In₂O₃, InZnO, ZnSnO, InGaZnO, or ZnGaSnO, a two-dimensional (2D) semiconductor material such as MoS₂, MoSe₂, WS₂, WSe₂, or SnS₂, or a nanostructure, such as nanodots, nanotubes, or graphene.

For example, after the channel layer is formed along the entire sidewall of the tunnel insulating layer 16, the first and second channel layers 17A and 17B may be respectively formed on both sidewalls of the tunnel insulating layer 16 in the first horizontal direction A-A′ by etching and removing the channel layer formed on the sidewalls of the tunnel insulating layer 16 in the second horizontal direction B-B′. Because the channel layer is formed along the entire sidewall of the tunnel insulating layer 16, a portion of the channel layer may protrude into the hole (e.g., H of FIG. 7B) along the tunnel insulating layer 16 protruding into the hole. Therefore, during an etching process, the first and second channel layers 17A and 17B may be respectively formed on both sidewalls of the tunnel insulating layer 16 in the first horizontal direction A-A′ by etching and removing portions protruding into the hole (e.g., H of FIG. 7B).

Thereafter, the hole (e.g., H of FIG. 7B) may be filled with a core insulating layer 18. The core insulating layer 18 may include an insulating material, such as oxide.

The blocking insulating layer 14, the first charge trap layer 15A, the tunnel insulating layer 16, and the first channel layer 17A, which are sequentially formed on the first sidewall SW1, may be defined as a first plug pattern, and the blocking insulating layer 14, the second charge trap layer 15B, the tunnel insulating layer 16, and the second channel layer 17B, which are sequentially formed on the second sidewall SW2, may be defined as a second plug pattern.

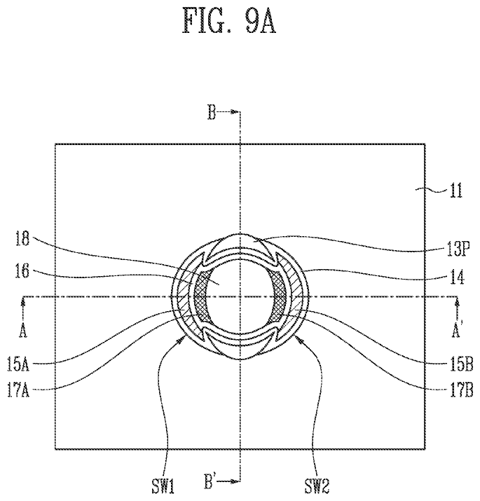

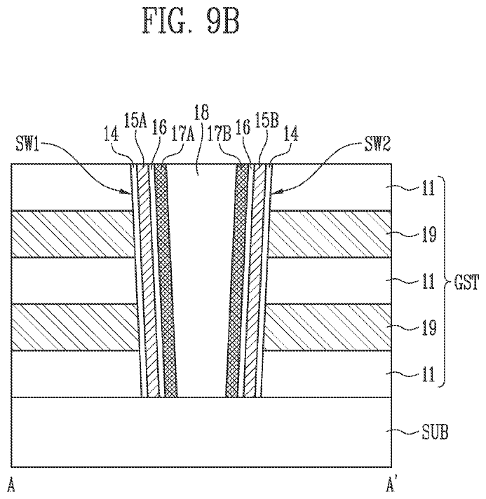

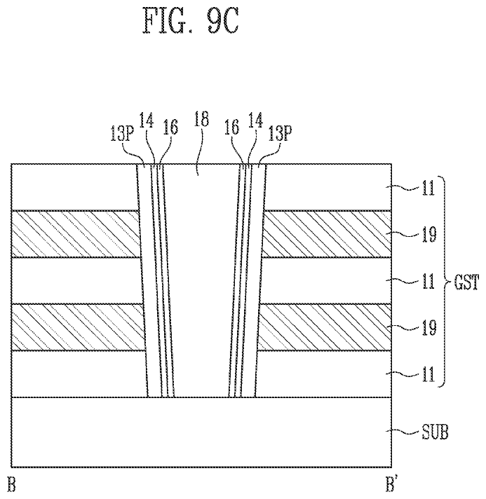

Referring to FIGS. 9A, 9B, and 9C, an etching process may be performed so that the sidewall of the stacked structure (e.g., ST of FIGS. 8B and 8C) is exposed, and the exposed second material layers (e.g., 12 of FIGS. 8B and 8C) may be removed. Thereafter, third material layers 19 may be formed in spaces in which the second material layers (e.g., 12 of FIGS. 8B and 8C) are removed. The third conductive layers 19 may include a conductive material, such as polysilicon, tungsten, or metal. Therefore, a gate stacked structure GST including the first material layers 11 and the third material layers 19 may be formed.

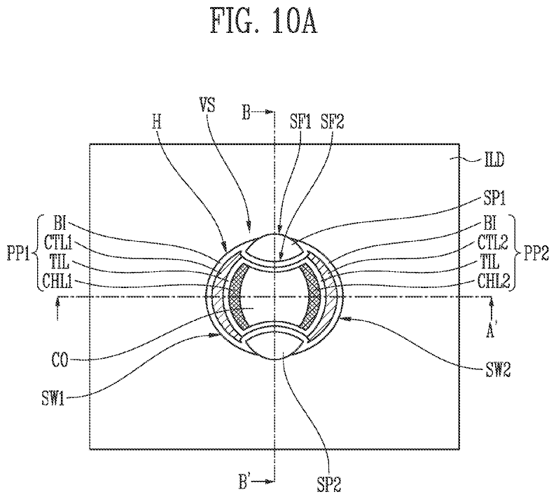

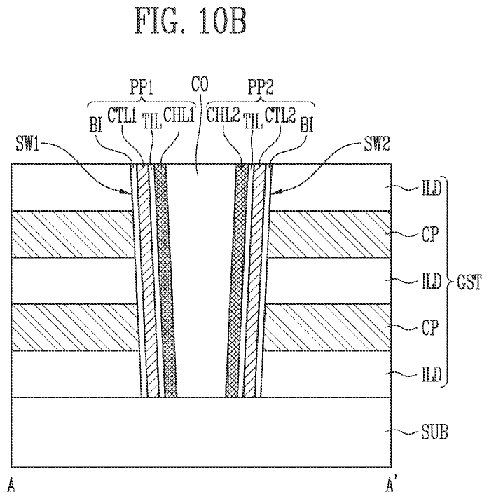

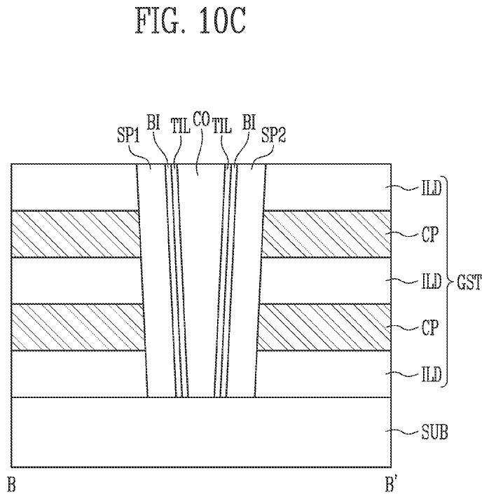

FIGS. 10A, 10B, and 10C are a plan view and sectional views for explaining a semiconductor device according to an embodiment of the present disclosure.

Referring to FIGS. 10A, 10B, and 10C, the semiconductor device may include a gate stacked structure GST and a vertical structure VS extending in the gate stacked structure GST in a vertical direction in relation to a substrate SUB.

The gate stacked structure GST may include conductive layers CP and interlayer insulating layers ILD, which are alternatingly stacked. The conductive layers CP may be gate electrodes of select transistors, memory cells, etc. The conductive layers CP may be select lines coupled to the select transistors and word lines coupled to the memory cells. The conductive layers CP may include a conductive material, such as polysilicon, tungsten, or metal. The interlayer insulating layers ILD may function to insulate the stacked conductive layers CP from each other. The interlayer insulating layers ILD may include an insulating material, such as oxide or nitride. Each of the interlayer insulating layers ILD and the conductive layers CP may have a structure protruding toward the vertical structure VS in a horizontal direction while alternatingly stacked in the vertical direction.

The vertical structure VS may penetrate the gate stacked structure GST and may extend in the vertical direction in relation to the substrate SUB. That is, the vertical structure VS may extend in the stacking direction of the gate stacked structure GST. The stacking direction of the gate stacked structure GST may be defined as the direction in which the conductive layers CP and the interlayer insulating layers ILD that are included in the gate stacked structure GST are alternatingly stacked. The vertical structure VS may be disposed in a hole H that passes through the gate stacked structure GST.

The vertical structure VS may include a first plug pattern PP1, a second plug pattern PP2, a first separation pattern SP1, a second separation pattern SP2, and a core insulating layer CO. The first plug pattern PP1, the second plug pattern PP2, the first separation pattern SP1, the second separation pattern SP2, and the core insulating layer CO may extend in the vertical direction in relation to the substrate SUB.

The core insulating layer CO may be formed in the central region of the vertical structure VS and may include an insulating material such as oxide.

The first plug pattern PP1 and the second plug pattern PP2 may have symmetrical structures along a first horizontal direction A-A′ of the hole H, which penetrates the gate stacked structure GST and extends in a vertical direction. The first horizontal direction A-A′ may be a direction horizontal to the substrate SUB.

For example, the first plug pattern PP1 may include a blocking insulating layer BI formed along the first sidewall SW1 of the hole H, a first charge trap layer CTL1 contacting the inner wall of the blocking insulating layer BI, a tunnel insulating layer TIL contacting the inner wall of the first charge trap layer CTL1, and a first channel layer CHL1 contacting the inner wall of the tunnel insulating layer TIL. The first channel layer CHL1 may contact the sidewall of the core insulating layer CO, the tunnel insulating layer TIL may contact the outer wall of the first channel layer CHL1, the first charge trap layer CTL1 may contact the outer wall of the tunnel insulating layer TIL, and the blocking insulating layer BI may contact the outer wall of the first charge trap layer CTL1.

For example, the second plug pattern PP2 may include a blocking insulating layer BI formed along the second sidewall SW2 of the hole H, a second charge trap layer CTL2 contacting the inner wall of the blocking insulating layer BI, a tunnel insulating layer TIL contacting the inner wall of the second charge trap layer CTL2, and a second channel layer CHL2 contacting the inner wall of the tunnel insulating layer TIL. The second channel layer CHL2 may contact the sidewall of the core insulating layer CO, the tunnel insulating layer TIL may contact the outer wall of the second channel layer CHL2, the second charge trap layer CTL2 may contact the outer wall of the tunnel insulating layer TIL, and the blocking insulating layer BI may contact the outer wall of the second charge trap layer CTL2.

The first and second channel layers CHL1 and CHL2 may be regions in which the channels of select transistors, memory cells, etc. are formed. Each of the first and second channel layers CHL1 and CHL2 may include a semiconductor material, such as silicon or germanium, or a nanostructure, such as nanodots, nanotubes, or graphene. The tunnel insulating layer TIL may be a layer in which charges are tunneled by F-N tunneling or like and may include an insulating material, such as oxide or nitride. Each of the first and second charge trap layers CTL1 and CTL2 may include a charge trapping material, nitride, a variable resistance material or a nanostructure, or a combination thereof. The blocking insulating layer BI may include a high-dielectric layer.

The first separation pattern SP1 and the second separation pattern SP2 may have symmetrical structures along the second horizontal direction B-B′ of the hole H. The second horizontal direction B-B′ may be a direction that is orthogonal to the first horizontal direction A-A′ and horizontal to the substrate SUB. The first separation pattern SP1 and the second separation pattern SP2 may extend in a vertical direction in relation to the substrate SUB. Each of the first separation pattern SP1 and the second separation pattern SP2 may have a first sidewall SF1 contacting the hole H and a second sidewall SF2 protruding into the hole respectively. For example, the first sidewall SF1 may be a curved surface that is convex in relation to outside the hole H, and the second sidewall SF2 may be a curved surface that is convex in relation to the center of the hole H.

Each of the first separation pattern SP1 and the second separation pattern SP2 may be disposed to contact a boundary portion between the first sidewall SW1 and the second sidewall SW2 of the hole H.

Each of the first separation pattern SP1 and the second separation pattern SP2 may include an insulating material. For example, each of the first separation pattern SP1 and the second separation pattern SP2 may be formed of an oxide layer or a silicon oxide layer.

The blocking insulating layer BI of the first plug pattern PP1 and the second plug pattern PP2 may be formed along the sidewalls of the first separation pattern SP1 and the second separation pattern SP2. That is, the blocking insulating layer BI of the first plug pattern PP1 and the blocking insulating layer BI of the second plug pattern PP2 may be formed along the sidewalls of the first separation pattern SP1 and the second separation pattern SP2 and may be coupled to each other. Furthermore, the tunnel insulating layer TIL of the first plug pattern PP1 and the tunnel insulating layer TIL of the second plug pattern PP2 may be formed along the inner walls of the blocking insulating layers BI and may be coupled to each other.

The first charge trap layer CTL1 of the first plug pattern PP1 and the second charge trap layer CTL2 of the second plug pattern PP2 may be spaced apart from each other by the first separation pattern SP1 and the second separation pattern SP2. Also, the first channel layer CHL1 of the first plug pattern PP1 and the second channel layer CHL2 of the second plug pattern PP2 may be spaced apart from each other by the first separation pattern SP1 and the second separation pattern SP2.

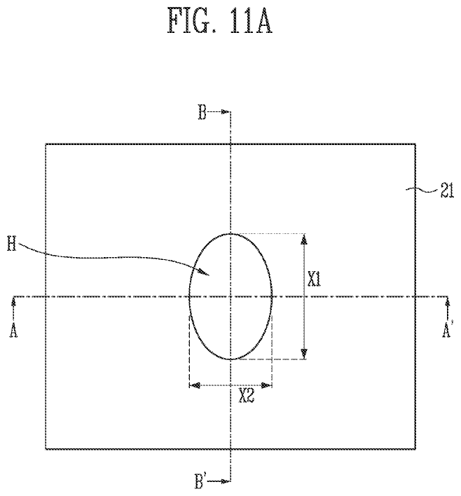

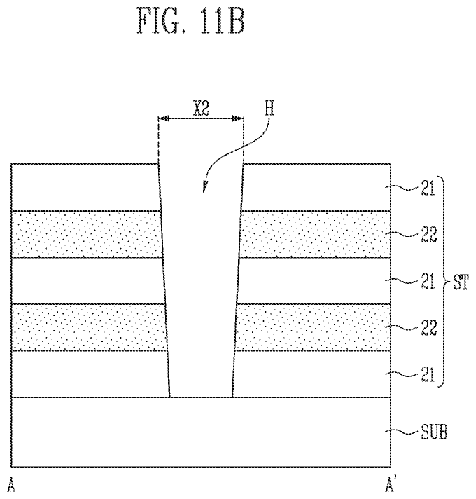

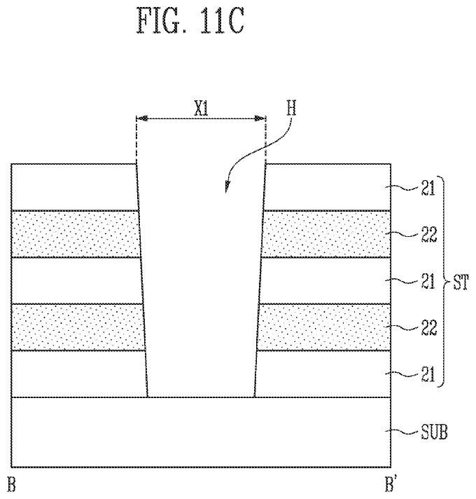

FIGS. 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, and 19C are plan views and sectional views for explaining a method of manufacturing a semiconductor device according to an embodiment of the present disclosure.

Referring to FIGS. 11A, 11B, and 11C, a stacked structure ST may be formed on a substrate SUB. The stacked structure ST may include first material layers 21 and second material layers 22, which are alternatingly stacked. The first and second material layers 21 and 22 may be stacked in a vertical direction in relation to the substrate SUB. The first and second material layers 21 and 22 may be formed through a deposition process, such as chemical vapor deposition (CVD).

The first material layers 21 may include a material having an etch selectivity that is higher than that of the second material layers 22. In an example, each of the first material layers 21 may include an insulating material, such as oxide, and each of the second material layers 22 may include a sacrificial material, such as nitride. In an example, each of the first material layers 21 may include an insulating material such as oxide, and each of the second material layers 22 may include a conductive material, such as polysilicon or tungsten.

Then, a hard mask pattern (not illustrated) may be formed on the stacked structure ST, and a hole H passing through at least a portion of the stacked structure ST may be formed by performing an etching process by using the hard mask pattern. The hole H may partially extend into the substrate SUB.

The hole H may be formed such that the width X2 thereof in a first horizontal direction A-A′ is narrower than the width X1 thereof in a second horizontal direction B-B′. For example, the cross-section of the hole H may have an elliptical shape.

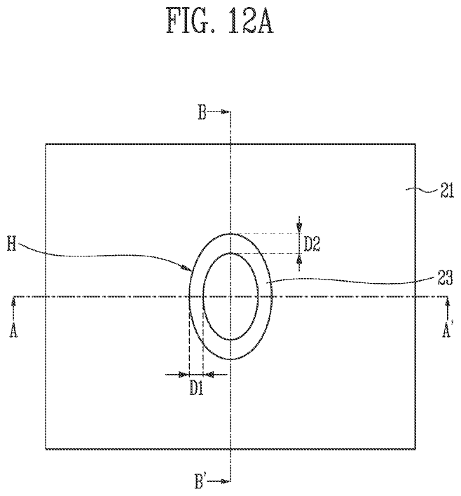

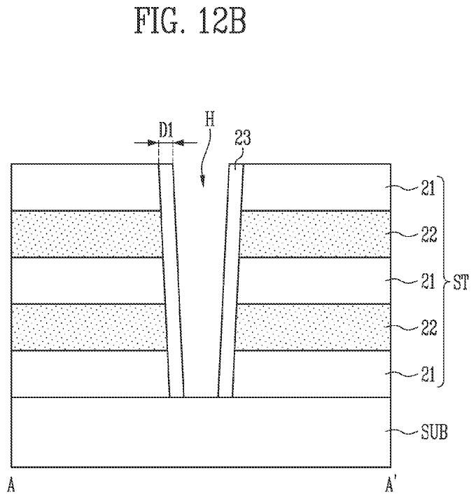

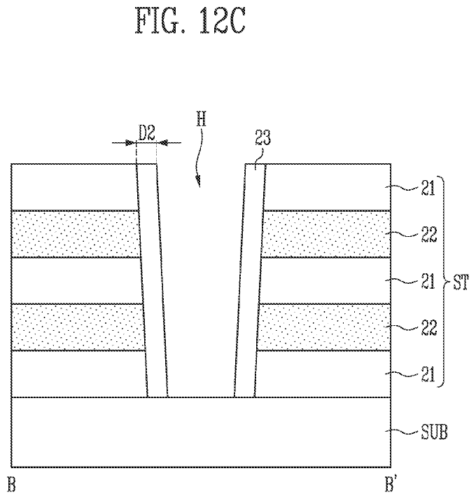

Referring to FIGS. 12A, 12B, and 12C, an insulating layer 23 may be formed along the sidewall of the hole H. The insulating layer 23 may be an oxide layer. The insulating layer 23 may include silicon oxide. The thickness D1 of the insulating layer 23 formed on the sidewall of the hole H in the first horizontal direction A-A′ may be formed to be different from the thickness D2 of the insulating layer 23 formed on the sidewall of the hole H in the second horizontal direction B-B′. The thickness D1 of the insulating layer 23 formed on the sidewall of the hole H in the first horizontal direction A-A′ may be less than the thickness D2 of the insulating layer 23 formed on the sidewall of the hole H in the second horizontal direction B-B′.

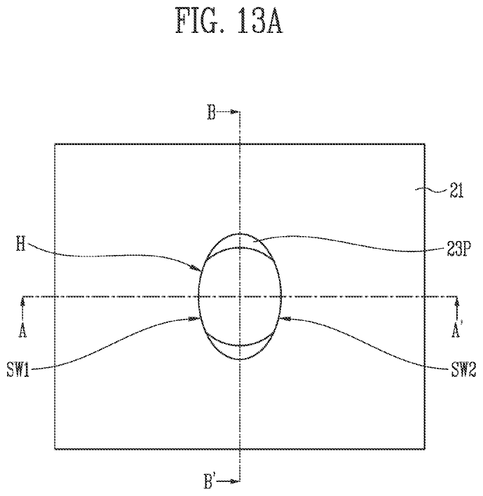

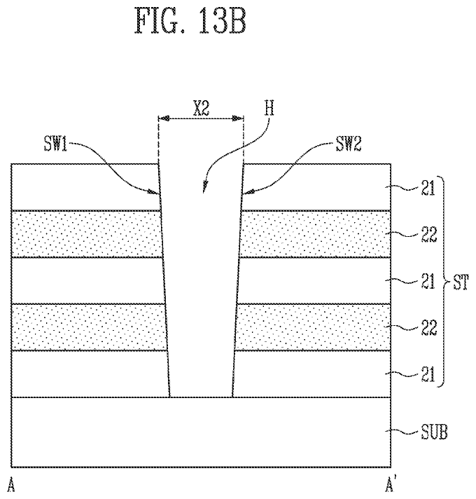

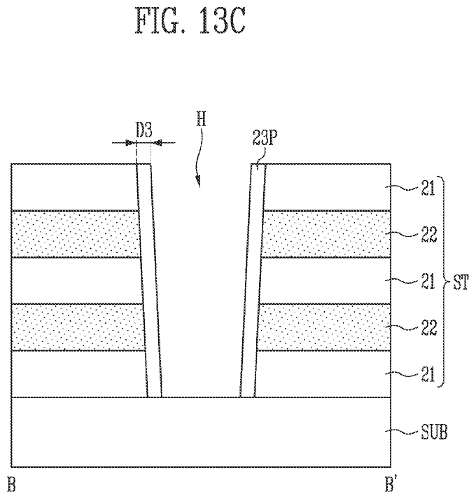

Referring to FIGS. 13A, 13B, and 13C, the insulating layer (e.g., 23 of FIGS. 12A, 12B, and 12C) may be etched to a certain thickness by performing an etching process and may then be partially removed. The etching process may be performed through an isotropic etching process. For example, a portion of the insulating layer 23 may be etched and removed such that the sidewall of the hole H in the first horizontal direction A-A′ is exposed. During the etching process, the thickness of the insulating layer 23 formed on the sidewall of the hole H in the first horizontal direction A-A′ may be less than that of the insulating layer 23 formed on the sidewall of the hole H in the second horizontal direction B-B′. Accordingly, even though the insulating layer 23 is etched such that the sidewall of the hole H in the first horizontal direction A-A′ is exposed, the insulating layer 23 may remain on the sidewall of the hole H in the second horizontal direction B-B′. Furthermore, the etching rate in the first horizontal direction A-A′ may be higher than that in the second horizontal direction B-B′ due to the differences between surface areas of the insulating layer 23 exposed to an etching agent and between surface angles thereof during the isotropic etching process. Therefore, separation patterns 23P may be formed on both sidewalls of the hole H in the second horizontal direction B-B′. A horizontal cross-section of each separation pattern 23P may have a crescent shape. Before the etching process is performed, the thickness D3 of the separation pattern 23P may be less than the thickness (e.g., D2 of FIG. 12C) of the insulating layer 23 formed on the sidewall of the hole H in the second horizontal direction B-B′.

The sidewall of the hole H may be divided into a first sidewall SW1 and a second sidewall SW2 based on the separation patterns 23P. For example, both sides of the hole H in the first horizontal direction A-A′ may be divided into the first sidewall SW1 and the second sidewall SW2.

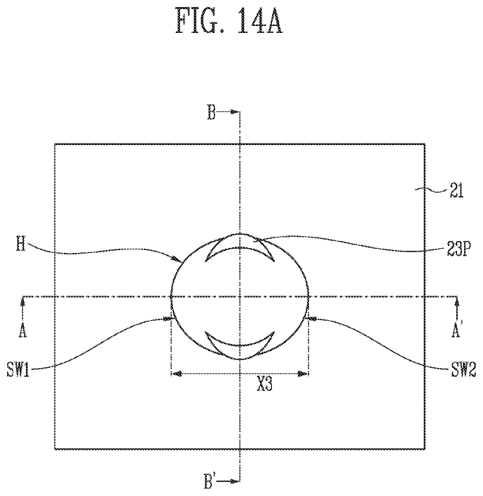

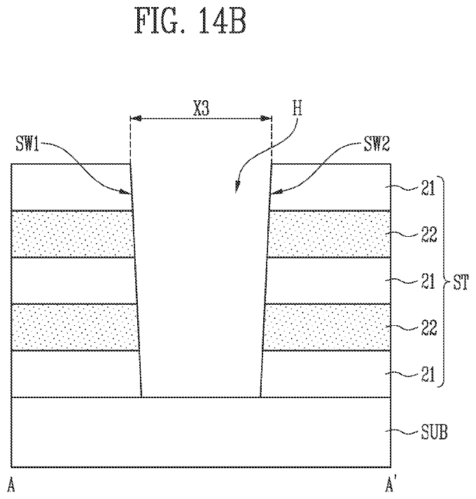

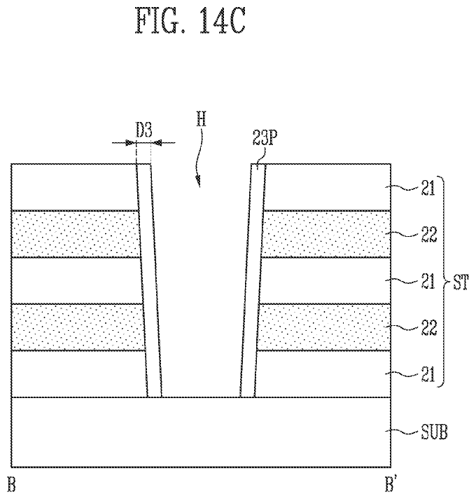

Referring to FIGS. 14A, 14B, and 14C, an etching process may be performed to expand the hole H. For example, the width X3 of the hole H in the first horizontal direction A-A′ may be extended by etching the first sidewall SW1 and the second sidewall SW2 of the hole H, which are exposed.

Both ends of each separation pattern 23P may protrude into the hole H through the etching process.

During the etching process, the sidewall of the hole H in the second horizontal direction B-B′ may be prevented from being etched by the separation patterns 23P, and thus, the width of the hole H in the second horizontal direction B-B′ might not extend.

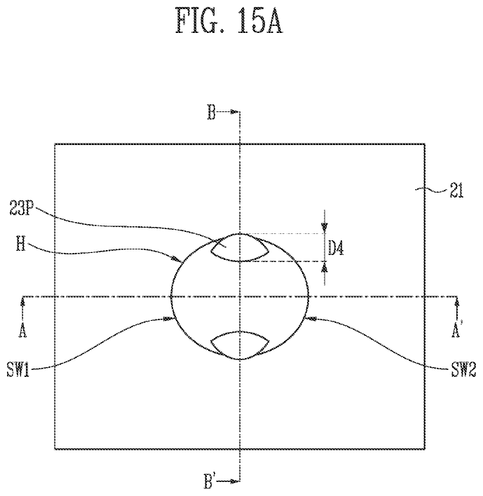

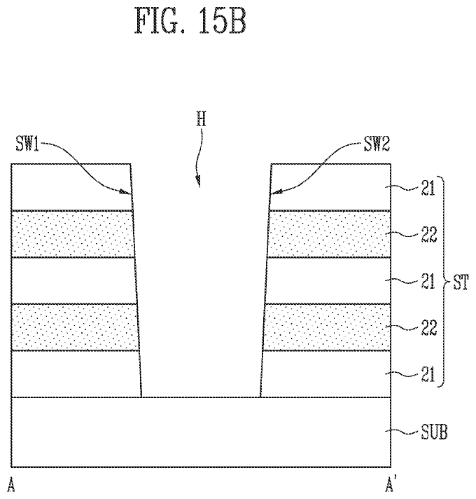

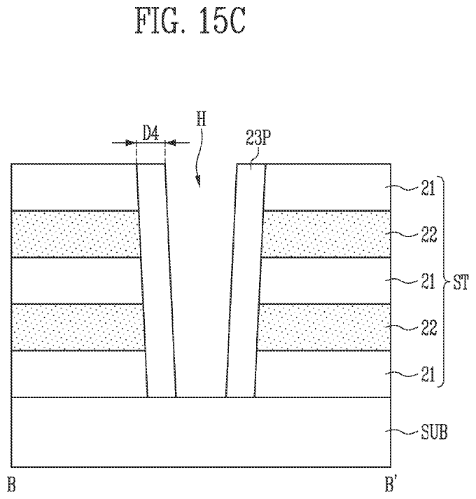

Referring to FIGS. 15A, 15B, and 15C, a selective deposition process may be performed such that the inner sidewalls of the separation patterns 23P are formed to be convex in relation to the center of the hole H. For example, oxide or silicon oxide may be selectively deposited on the inner sidewalls of the separation patterns 23P. Therefore, the separation patterns 23P may further protrude toward the center of the hole H.

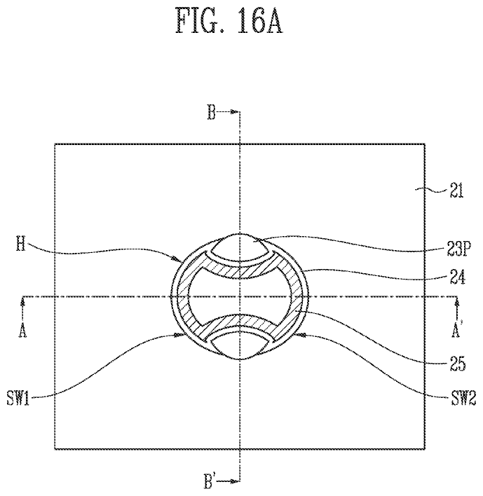

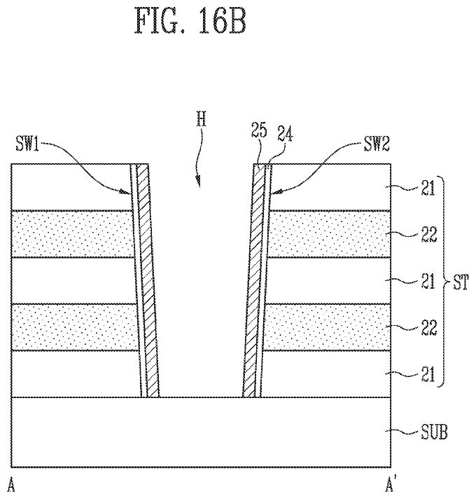

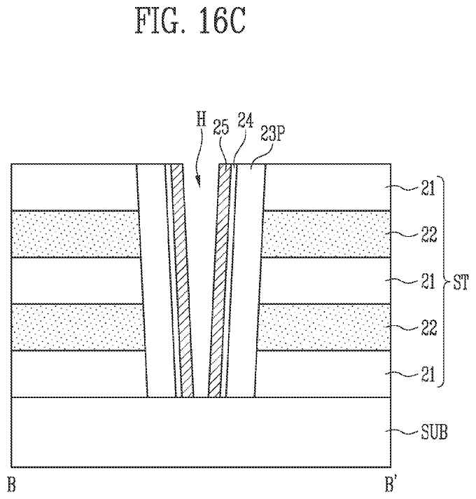

Referring to FIGS. 16A, 16B, and 16C, a blocking insulating layer 24 may be formed along the exposed first and second sidewalls SW1 and SW2 of the hole H and the exposed sidewalls of the separation patterns 23P. The blocking insulating layer 24 may be a high-dielectric layer.

Thereafter, a charge trap layer 25 may be formed along the inner wall of the blocking insulating layer 24. The data trap layer 25 may include a charge trapping material, nitride, a variable resistance material, or a nanostructure, or a combination thereof.

The blocking insulating layer 24 and the charge trap layer 25 that are sequentially formed along the sidewalls of the separation patterns 23P may protrude into the hole.

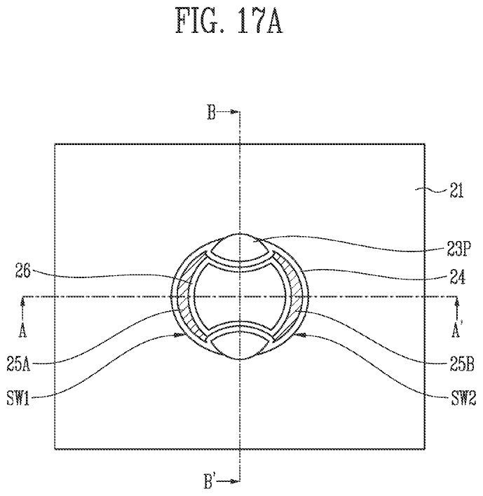

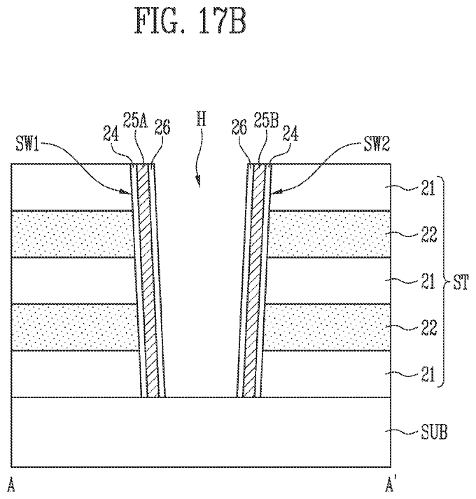

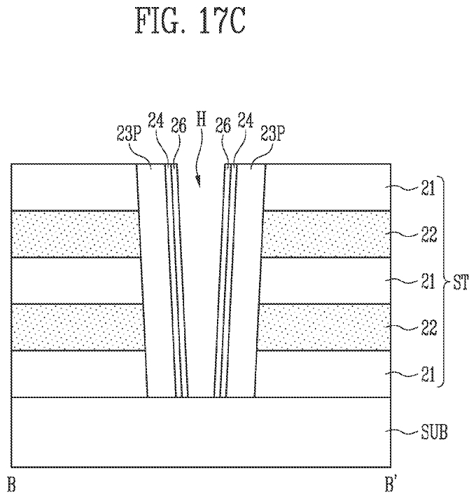

Referring to FIGS. 17A, 17B, and 17C, a first charge trap layer 25A and a second charge trap layer 25B may be formed by partially removing the charge trap layer (e.g., 25 of FIG. 16A). For example, the charge trap layer (e.g., 25 of FIG. 16A) adjacent to the separation patterns 23P may be removed by performing an etching process. That is, the charge trap layer (e.g., 25 of FIG. 16A) protruding into the hole H may be etched and removed, and thus, the first charge trap layer 25A and the second charge trap layer 25B, which are spaced apart from each other, may be formed. The blocking insulating layer 24 may be exposed where a portion of the charge trap layer (e.g., 25 of FIG. 16A) has been removed.

Thereafter, a tunnel insulating layer 26 may be formed along the sidewalls of the first charge trap layer 25A and the second charge trap layer 25B. The tunnel insulating layer 26 may be a layer in which charges are tunneled by F-N tunneling or like and may include an insulating material such as oxide or nitride. The tunnel insulating layer 26 may be formed to cover the exposed sidewall of the blocking insulating layer 24.

The tunnel insulating layer 26 adjacent to the separation patterns 23P may protrude into the hole.

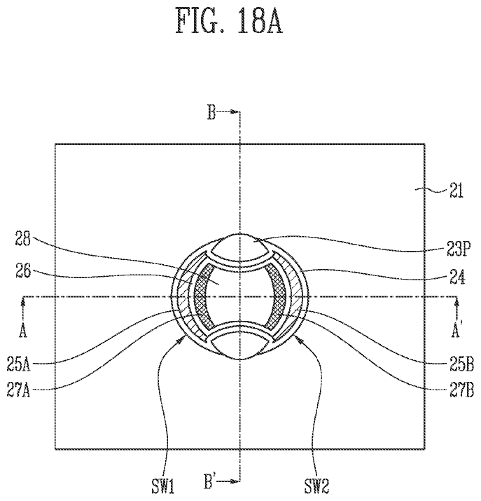

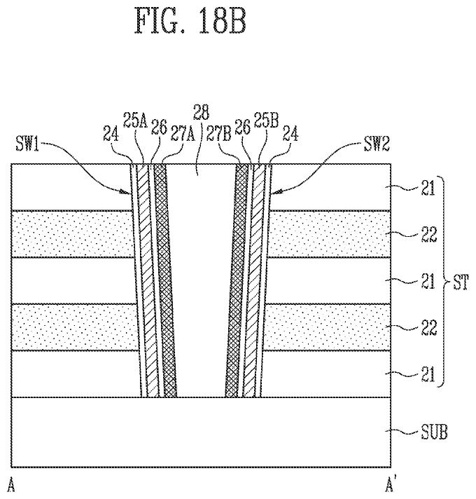

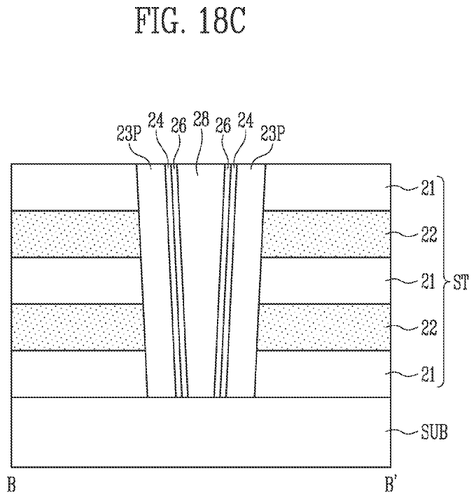

Referring to FIGS. 18A, 18B, and 18C, first and second channel layers 27A and 27B are respectively formed on both sidewalls of the tunnel insulating layer 26 in the first horizontal direction A-A′. For example, each of the first and second channel layers 27A and 27B may include a semiconductor material, such as silicon or germanium, an oxide semiconductor material, such as ZnO, In₂O₃, InZnO, ZnSnO, InGaZnO, or ZnGaSnO, a two-dimensional (2D) semiconductor material, such as MoS₂, MoSe₂, WS₂, WSe₂, or SnS₂, or a nanostructure, such as nanodots, nanotubes, or graphene.

For example, after the channel layer is formed along the entire sidewall of the tunnel insulating layer 26, the first and second channel layers 27A and 27B may be respectively formed on both sidewalls of the tunnel insulating layer 26 in the first horizontal direction A-A′ by etching and removing the channel layer formed on the sidewalls of the tunnel insulating layer 26 in the second horizontal direction B-B′. Because the channel layer is formed along the entire sidewall of the tunnel insulating layer 26, a portion of the channel layer may protrude into the hole along the tunnel insulating layer 26 protruding into the hole. Therefore, during an etching process, the first and second channel layers 27A and 27B may be respectively formed on both sidewalls of the tunnel insulating layer 26 in the first horizontal direction A-A′ by etching and removing portions protruding into the hole.

Thereafter, the hole may be filled with a core insulating layer 28. The core insulating layer 28 may include an insulating material, such as oxide.

The blocking insulating layer 24, the first charge trap layer 25A, the tunnel insulating layer 26, and the first channel layer 27A, which are sequentially formed on the first sidewall SW1, may be defined as a first plug pattern, and the blocking insulating layer 24, the second charge trap layer 25B, the tunnel insulating layer 26, and the second channel layer 27B, which are sequentially formed on the second sidewall SW2, may be defined as a second plug pattern.

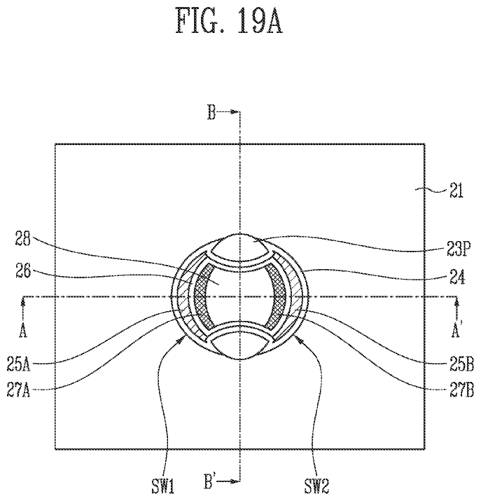

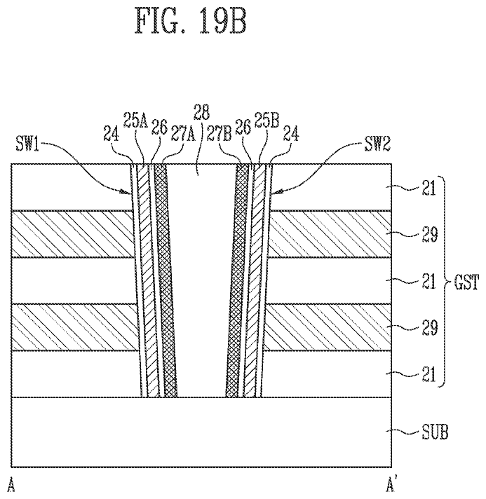

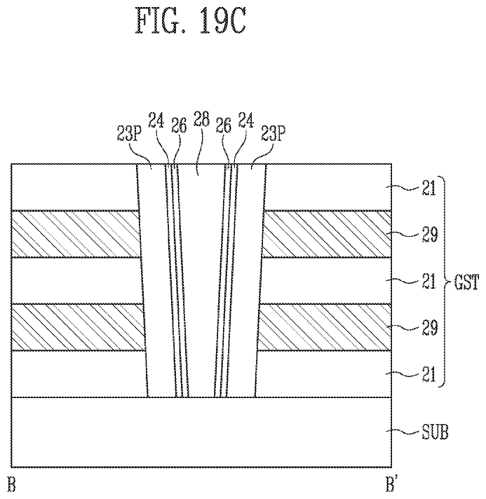

Referring to FIGS. 19A, 19B, and 19C, an etching process may be performed so that the sidewall of the stacked structure (e.g., ST of FIGS. 18B and 18C) is exposed, and the exposed second material layers (e.g., 22 of FIGS. 18B and 18C) may be removed. Thereafter, third material layers 29 may be formed in spaces in which the second material layers (e.g., 22 of FIGS. 18B and 18C) are removed. The third conductive layers 29 may include a conductive material, such as polysilicon, tungsten, or metal. Therefore, a gate stacked structure GST including the first material layers 21 and the third material layers 29 may be formed.

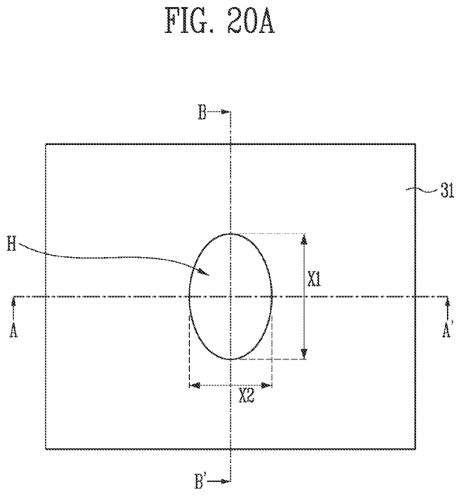

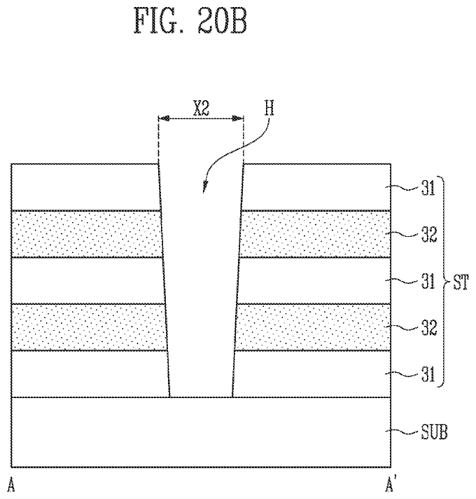

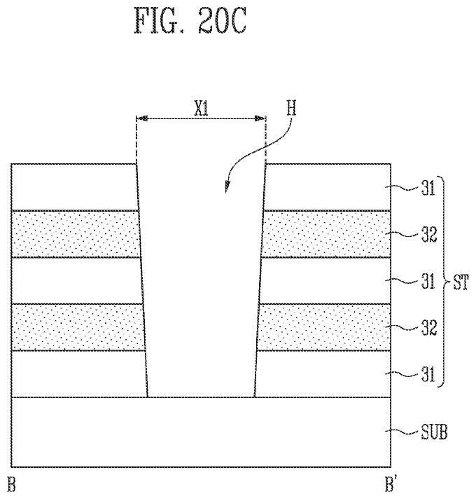

FIGS. 20A, 20B, 20C, 21A, 21B, 21C, 22A, 22B, 22C, 23A, 23B, 23C, 24A, 24B, 24C, 25A, 25B, 25C, 26A, 26B, 26C, 27A, 27B, 27C, 28A, 28B, 28C, 29A, 29B, and 29C are plan views and sectional views for explaining a method of manufacturing a semiconductor device according to an embodiment of the present disclosure.

Referring to FIGS. 20A, 20B, and 20C, a stacked structure ST may be formed on a substrate SUB. The stacked structure ST may include first material layers 31 and second material layers 32, which are alternatingly stacked. The first and second material layers 31 and 32 may be stacked in a vertical direction in relation to the substrate SUB. The first and second material layers 31 and 32 may be formed through a deposition process, such as chemical vapor deposition (CVD).

The first material layers 31 may include a material having an etch selectivity that is higher than that of the second material layers 32. In an example, each of the first material layers 31 may include an insulating material, such as oxide, and each of the second material layers 32 may include a sacrificial material, such as nitride. In an example, each of the first material layers 31 may include an insulating material such as oxide, and each of the second material layers 32 may include a conductive material, such as polysilicon or tungsten.

Then, a hard mask pattern (not illustrated) may be formed on the stacked structure ST, and a hole H passing through at least a portion of the stacked structure ST may be formed by performing an etching process by using the hard mask pattern. The hole H may partially extend into the substrate SUB.

The hole H may be formed such that the width X2 thereof in a first horizontal direction A-A′ is narrower than the width X1 thereof in a second horizontal direction B-B′. For example, the cross-section of the hole H may have an elliptical shape.

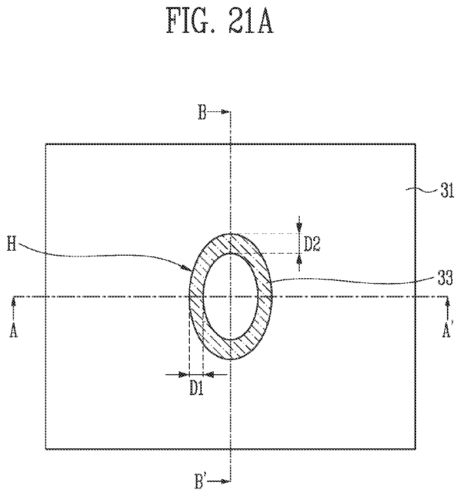

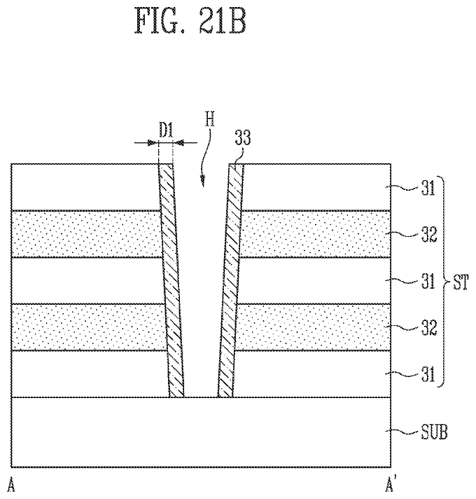

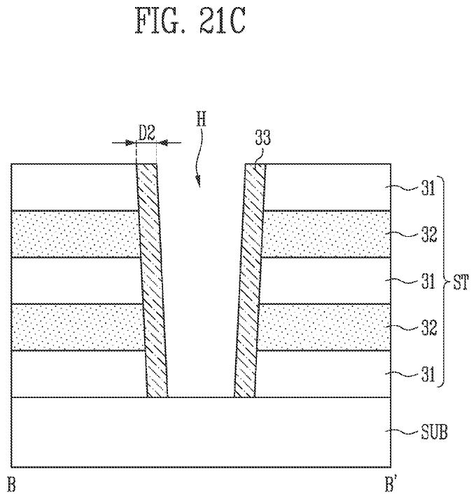

Referring to FIGS. 21A, 21B, and 21C, a sacrificial layer 33 is formed along the sidewall of the hole H. The sacrificial layer 33 may be a polysilicon layer. The thickness D1 of the sacrificial layer 33 formed on the sidewall of the hole H in the first horizontal direction A-A′ may be formed to be different from the thickness D2 of the sacrificial layer 33 formed on the sidewall of the hole H in the second horizontal direction B-B′. The thickness D1 of the sacrificial layer 33 formed on the sidewall of the hole H in the first horizontal direction A-A′ may be less than the thickness D2 of the sacrificial layer 33 formed on the sidewall of the hole H in the second horizontal direction B-B′.

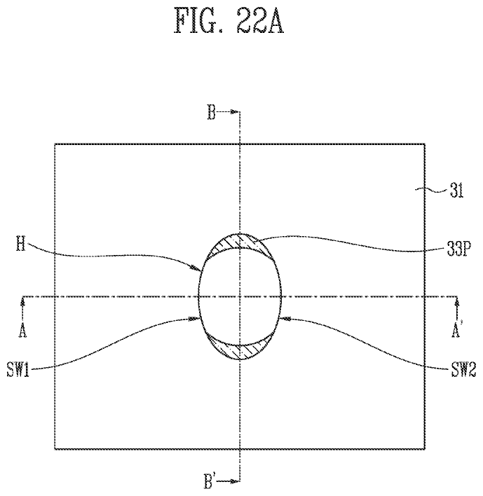

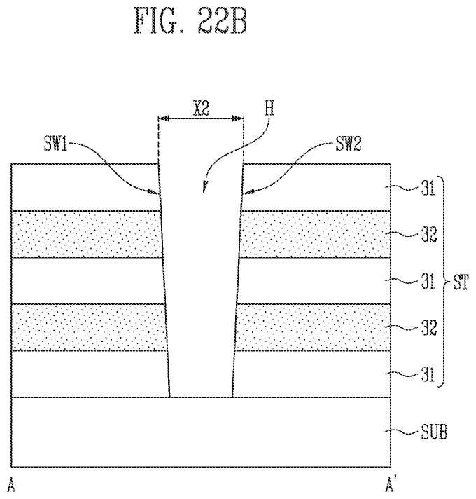

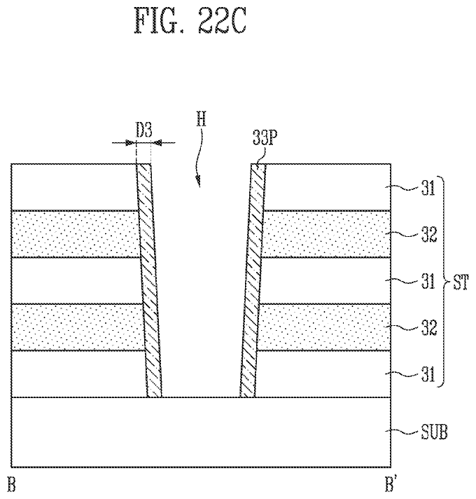

Referring to FIGS. 22A, 22B, and 22C, the sacrificial layer (e.g., 33 of FIGS. 21A, 21B, and 21C) may be etched to a certain thickness by performing an etching process and may then be partially removed. The etching process may be performed through an isotropic etching process. For example, a portion of the sacrificial layer 33 may be etched and removed such that the sidewall of the hole H in the first horizontal direction A-A′ is exposed. During the etching process, the thickness of the sacrificial layer 33 formed on the sidewall of the hole H in the first horizontal direction A-A′ may be less than that of the sacrificial layer 33 formed on the sidewall of the hole H in the second horizontal direction B-B′. Accordingly, even though the sacrificial layer 33 is etched such that the sidewall of the hole H in the first horizontal direction A-A′ is exposed, the sacrificial layer 33 may remain on the sidewall of the hole H in the second horizontal direction B-B′. Furthermore, the etching rate in the first horizontal direction A-A′ may be higher than that in the second horizontal direction B-B′ due to the differences between surface areas of the sacrificial layer 33 exposed to an etching agent and between surface angles thereof during the isotropic etching process. Therefore, preliminary separation patterns 33P may be formed on both sidewalls of the hole H in the second horizontal direction B-B′. The horizontal cross-section of each preliminary separation pattern 33P may have a crescent shape. Before the etching process is performed, the thickness D3 of the preliminary separation pattern 33P may be less than the thickness (e.g., D2 of FIG. 21C) of the sacrificial layer 33 formed on the sidewall of the hole H in the second horizontal direction B-B′.

The sidewall of the hole H may be divided into a first sidewall SW1 and a second sidewall SW2 based on the preliminary separation patterns 33P. For example, both sides of the hole H in the first horizontal direction A-A′ may be divided into the first sidewall SW1 and the second sidewall SW2.

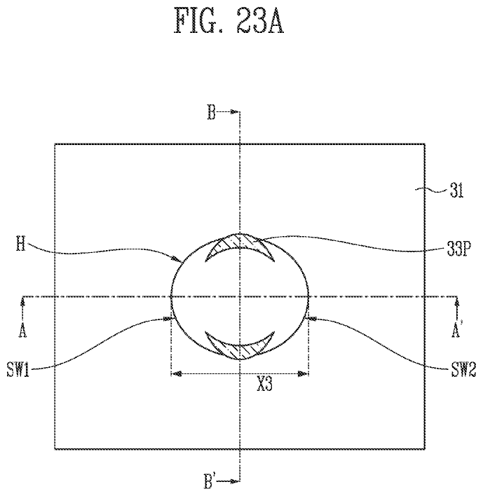

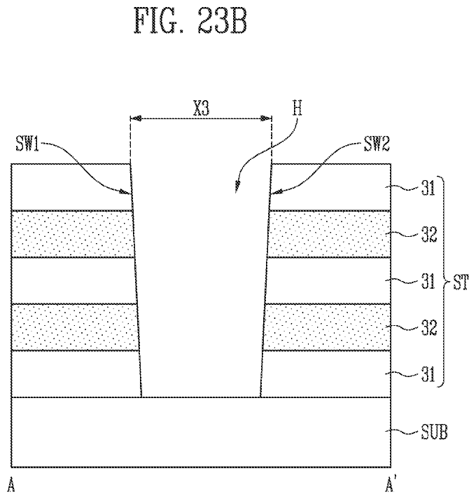

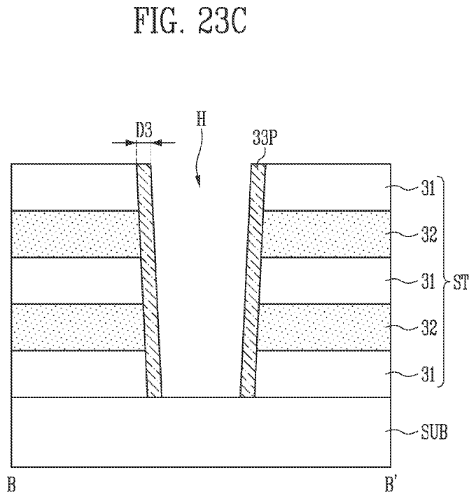

Referring to FIGS. 23A, 23B, and 23C, an etching process may be performed to expand the hole H. For example, the width X3 of the hole H in the first horizontal direction A-A′ may be extended by etching the first sidewall SW1 and the second sidewall SW2 of the hole H, which are exposed.

Both ends of each preliminary separation pattern 33P may protrude into the hole H through the etching process.

During the etching process, the sidewall of the hole H in the second horizontal direction B-B′ may be prevented from being etched by the preliminary separation patterns 33P, and thus, the width of the hole H in the second horizontal direction B-B′ might not extend.

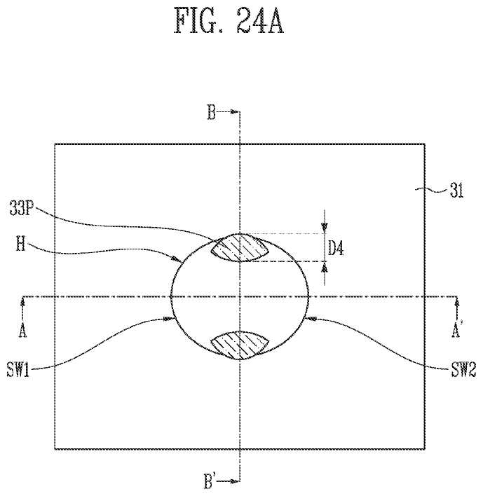

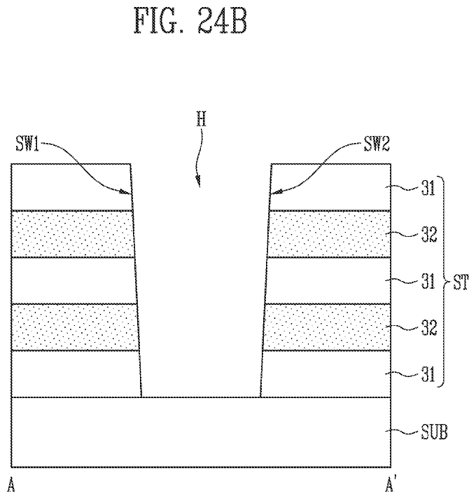

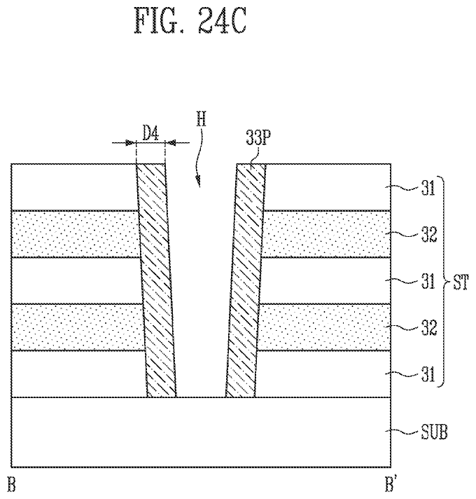

Referring to FIGS. 24A, 24B, and 24C, a selective deposition process may be performed such that the inner sidewalls of the preliminary separation patterns 33P are formed to be convex in relation to the center of the hole H. For example, a polysilicon material may be selectively deposited on the inner sidewalls of the preliminary separation patterns 33P. Therefore, the preliminary separation patterns 33P may further protrude toward the center of the hole H.

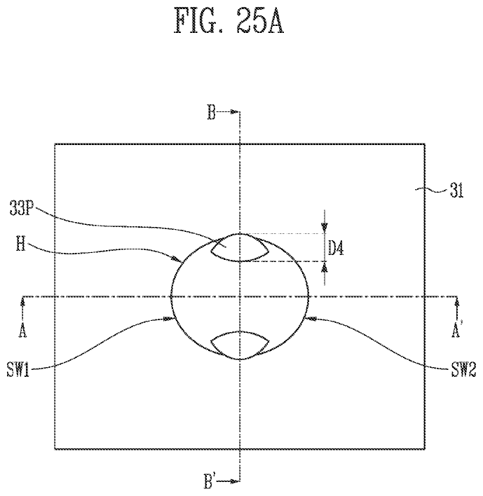

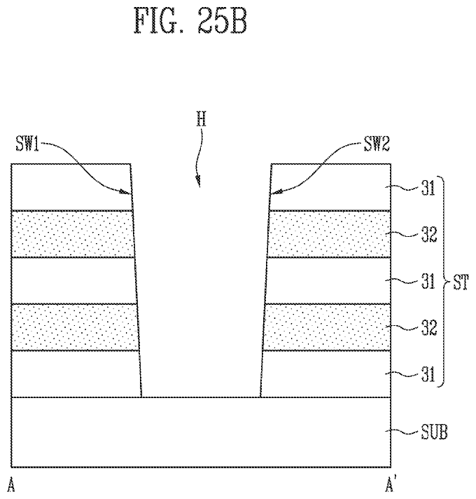

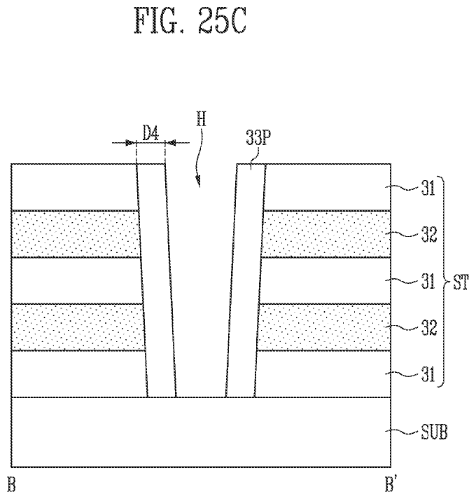

Referring to FIGS. 25A, 25B, and 25C, the preliminary separation patterns may be oxidized by performing an oxidization process, and thus, separation patterns 33P may be formed. That is, the separation patterns 33P including oxide may be formed by replacing the preliminary separation patterns made of polysilicon. Through the oxidization process, the separation patterns 33P may further protrude into the hole H compared to the preliminary separation patterns.

In the foregoing embodiment, after a selective deposition process is performed on the preliminary separation patterns 33P, as illustrated in FIGS. 24A, 24B, and 24C, the oxidization process is performed as illustrated in FIGS. 25A, 25B, and 25C, but the oxidization process may be performed without requiring the selective deposition process to be performed.

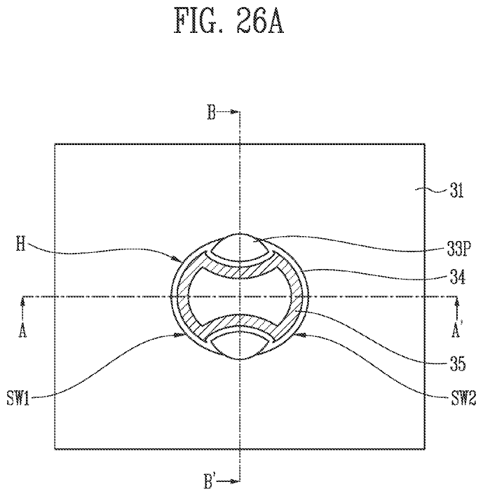

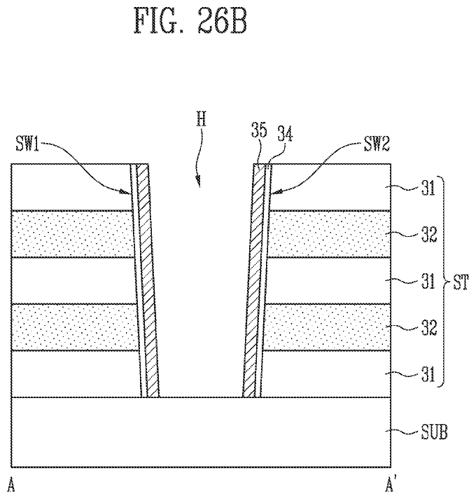

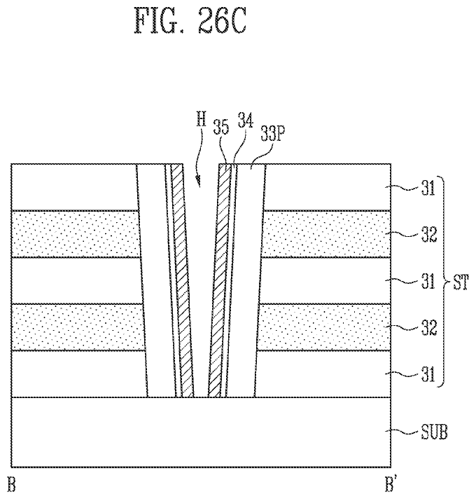

Referring to FIGS. 26A, 26B, and 26C, a blocking insulating layer 34 may be formed along the exposed first and second sidewalls SW1 and SW2 of the hole H and the exposed sidewalls of the separation patterns 33P. The blocking insulating layer 34 may be a high-dielectric layer.

Thereafter, a charge trap layer 35 may be formed along the inner wall of the blocking insulating layer 34. The data trap layer 35 may include a charge trapping material, nitride, a variable resistance material, or a nanostructure, or a combination thereof.

The blocking insulating layer 34 and the charge trap layer 35 that are sequentially formed along the sidewalls of the separation patterns 33P may protrude into the hole.

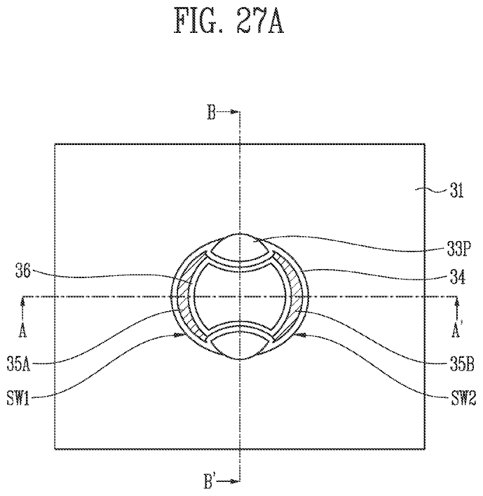

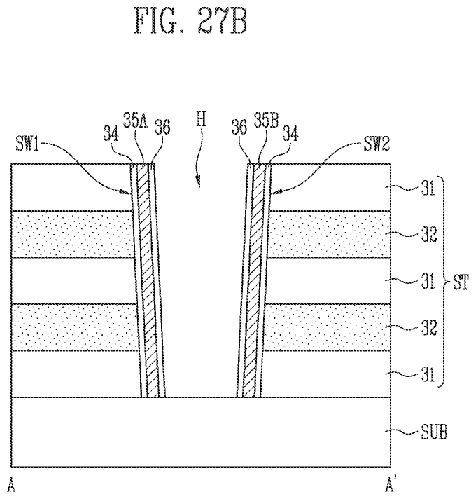

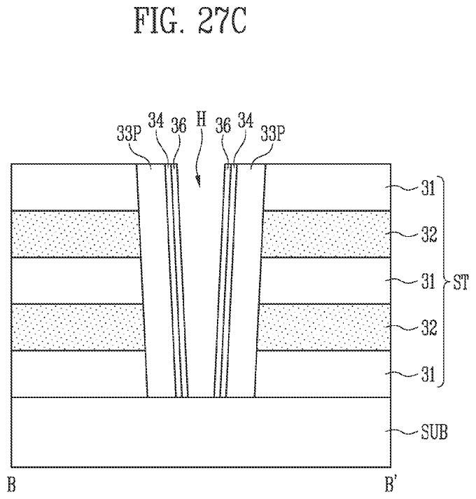

Referring to FIGS. 27A, 27B, and 27C, a first charge trap layer 35A and a second charge trap layer 35B may be formed by partially removing the charge trap layer (e.g., 35 of FIG. 26A). For example, the charge trap layer (e.g., 35 of FIG. 26A) adjacent to the separation patterns 33P may be removed by performing an etching process. That is, the charge trap layer (e.g., 35 of FIG. 26A) protruding into the hole may be etched and removed, and thus, the first charge trap layer 35A and the second charge trap layer 35B, which are spaced apart from each other, may be formed. The blocking insulating layer 34 may be exposed where a portion of the charge trap layer (e.g., 35 of FIG. 26A) has been removed.

Thereafter, a tunnel insulating layer 36 may be formed along the sidewalls of the first charge trap layer 35A and the second charge trap layer 35B. The tunnel insulating layer 36 may be a layer in which charges are tunneled by F-N tunneling or like and may include an insulating material such as oxide or nitride. The tunnel insulating layer 36 may be formed to cover the exposed sidewall of the blocking insulating layer 34.

The tunnel insulating layer 36 adjacent to the separation patterns 33P may protrude into the hole.

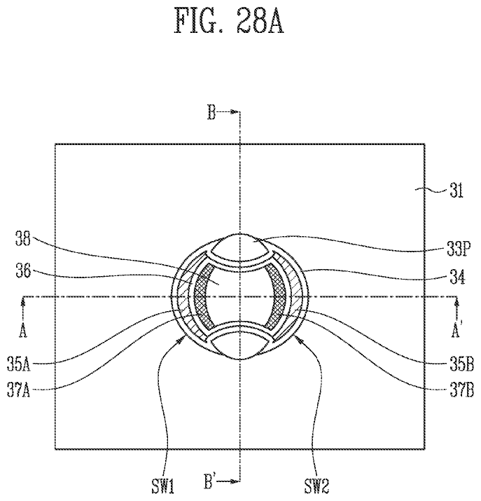

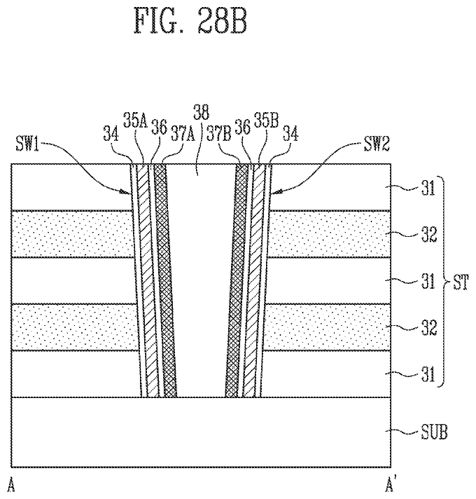

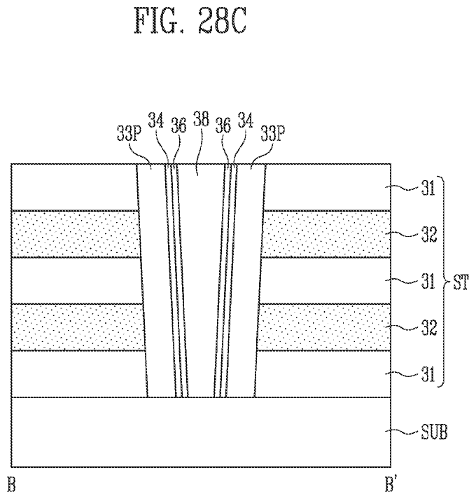

Referring to FIGS. 28A, 28B, and 28C, first and second channel layers 37A and 37B are respectively formed on both sidewalls of the tunnel insulating layer 36 in the first horizontal direction A-A′. For example, each of the first and second channel layers 37A and 37B may include a semiconductor material, such as silicon or germanium, an oxide semiconductor material, such as ZnO, In₂O₃, InZnO, ZnSnO, InGaZnO, or ZnGaSnO, a two-dimensional (2D) semiconductor material, such as MoS₂, MoSe₂, WS₂, WSe₂, or SnS₂, or a nanostructure, such as nanodots, nanotubes, or grapheme.

For example, after the channel layer is formed along the entire sidewall of the tunnel insulating layer 36, the first and second channel layers 37A and 37B may be respectively formed on both sidewalls of the tunnel insulating layer 36 in the first horizontal direction A-A′ by etching and removing the channel layer formed on the sidewalls of the tunnel insulating layer 36 in the second horizontal direction B-B′. Because the channel layer is formed along the entire sidewall of the tunnel insulating layer 36, a portion of the channel layer may protrude into the hole along the tunnel insulating layer 36 protruding into the hole. Therefore, during an etching process, the first and second channel layers 37A and 37B may be respectively formed on both sidewalls of the tunnel insulating layer 36 in the first horizontal direction A-A′ by etching and removing portions protruding into the hole.

Thereafter, the hole may be filled with a core insulating layer 38. The core insulating layer 38 may include an insulating material, such as oxide.

The blocking insulating layer 34, the first charge trap layer 35A, the tunnel insulating layer 36, and the first channel layer 37A, which are sequentially formed on the first sidewall SW1, may be defined as a first plug pattern, and the blocking insulating layer 34, the second charge trap layer 35B, the tunnel insulating layer 36, and the second channel layer 37B, which are sequentially formed on the second sidewall SW2, may be defined as a second plug pattern.

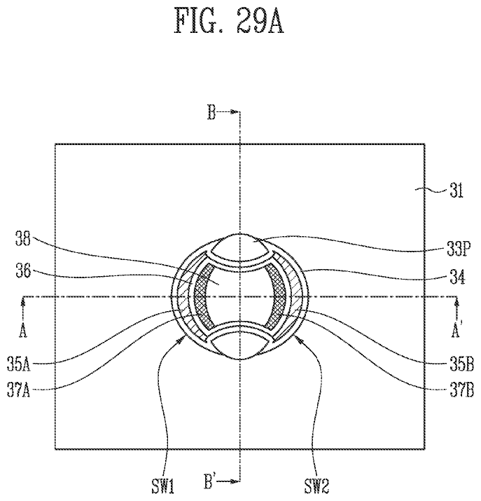

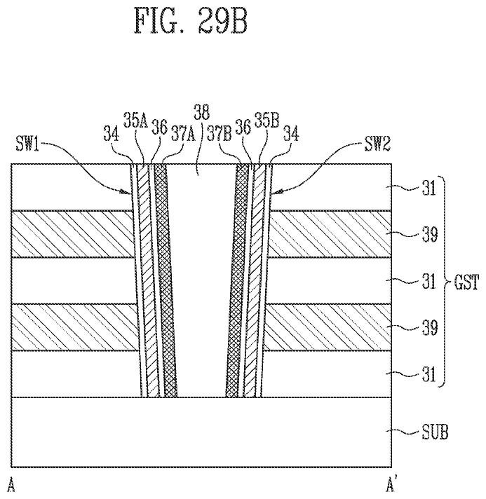

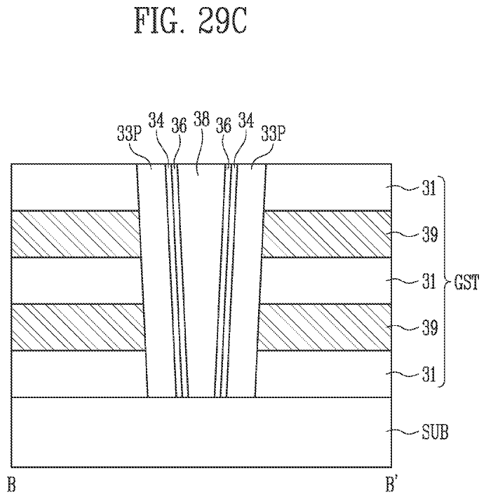

Referring to FIGS. 29A, 29B, and 29C, an etching process may be performed so that the sidewall of the stacked structure (e.g., ST of FIGS. 28B and 28C) is exposed, and the exposed second material layers (e.g., 32 of FIGS. 28B and 28C) may be removed. Thereafter, third material layers 39 may be formed in spaces in which the second material layers (e.g., 32 of FIGS. 28B and 28C) are removed. The third conductive layers 39 may include a conductive material, such as polysilicon, tungsten, or metal. Therefore, a gate stacked structure GST including the first material layers 31 and the third material layers 39 may be formed.

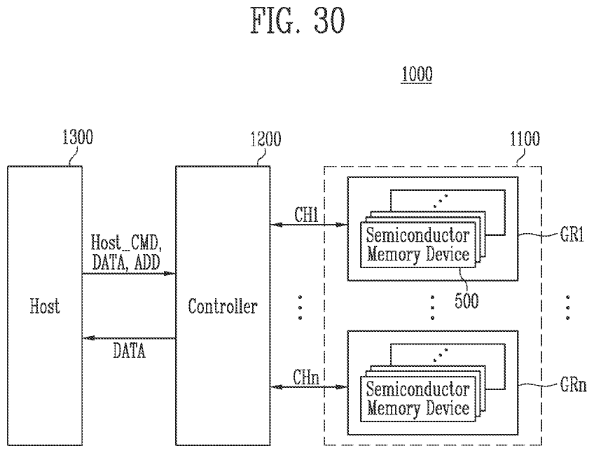

FIG. 30 is a block diagram illustrating a memory system including a semiconductor device according to an embodiment of the present disclosure.

Referring to FIG. 30, a memory system 1000 may include a memory device 1100, a controller 1200, and a host 1300. The memory device 1100 may include a plurality of semiconductor memory devices 500. The plurality of semiconductor memory devices 500 may be divided into a plurality of groups. In an embodiment of the present disclosure, although the host 1300 is illustrated and described as being included in the memory system 1000, the memory system 1000 may be configured to include only the controller 1200 and the memory device 1100, while the host 1300 is disposed outside the memory system 1000.

In FIG. 30, it is illustrated that the plurality of groups GR1 to GRn of the memory device 1100 communicate with the controller 1200 through first to n-th channels CH1 to CHn, respectively. Each semiconductor memory device 500 may be the semiconductor device, described above with reference to FIGS. 1A, 1B, and 1C or FIGS. 10A, 10B, and 10C.

The groups GR1 to GRn may individually communicate with the controller 1200 through one common channel. The controller 1200 may control the plurality of semiconductor memory devices 500 of the memory device 1100 through the plurality of channels CH1 to CHn.

The controller 1200 may be coupled between the host 1300 and the memory device 1100. The controller 1200 may access the memory device 1100 in response to a request from the host 1300. For example, the controller 1200 may control a read operation, a program operation, an erase operation, and a background operation of the memory device 1100 in response to a host command Host_CMD received from the host 1300. The host 1300 may transmit an address ADD and data DATA to be programmed, together with the host command Host_CMD, during a program operation and may transmit an address ADD, together with the host command Host_CMD, during a read operation. During a program operation, the controller 1200 may transmit the command corresponding to the program operation and the data DATA to be programmed to the memory device 1100. During a read operation, the controller 1200 may transmit the command corresponding to the read operation to the memory device 1100, receive read data DATA from the memory device 1100, and transmit the received data DATA to the host 1300. The controller 1200 may provide an interface between the memory device 1100 and the host 1300. The controller 1200 may run firmware for controlling the memory device 1100.

The host 1300 may include portable electronic devices, such as a computer, a personal digital assistant (PDA), a portable multimedia player (PMP), an MP3 player, a camera, a camcorder, and a mobile phone. The host 1300 may request the program operation, the read operation, the erase operation, etc. of the memory system 1000 through the host command Host_CMD. The host 1300 may transmit the host command Host_CMD corresponding to the program operation, the data DATA, and the address ADD to the controller 1200 to perform the program operation of the memory device 1100 and may transmit the host command Host_CMD corresponding to the read operation and the address ADD to the controller 1200 so as to perform the read operation. Here, the address ADD may be the logical address of the data.

The controller 1200 and the memory device 1100 may be integrated into a single semiconductor memory device. In an embodiment, the controller 1200 and the memory device 1100 may be integrated into a single semiconductor memory device to form a memory card. For example, the controller 1200 and the memory device 1100 may be integrated into a single semiconductor memory device to form a memory card, such as a personal computer memory card international association (PCMCIA), a compact flash card (CF), a smart media card (SM or SMC), a memory stick, a multimedia card (MMC, RS-MMC, or MMCmicro), an SD card (SD, miniSD, microSD, or SDHC), or a universal flash storage (UFS).

In an embodiment, the memory system 1000 may be provided as one of various elements of an electronic device, such as a computer, an ultra mobile PC (UMPC), a workstation, a net-book, a personal digital assistant (PDA), a portable computer, a web tablet, a wireless phone, a mobile phone, a smartphone, an e-book, a portable multimedia player (PMP), a game console, a navigation device, a black box, a digital camera, a three-dimensional (3D) television, a digital audio recorder, a digital audio player, a digital picture recorder, a digital picture player, a digital video recorder, a digital video player, a device capable of transmitting/receiving information in an wireless environment, one of various electronic devices for forming a home network, one of various electronic devices for forming a computer network, one of various electronic devices for forming a telematics network, a radio frequency identification (RFID) device, or one of various elements for forming a computing system.

In an embodiment, the memory device 1100 or the memory system 1000 may be mounted as various types of packages. For example, the memory device 1100 or the memory system 1000 may be packaged in a type, such as package on package (POP), ball grid arrays (BGAs), chip scale packages (CSPs), plastic leaded chip carrier (PLCC), plastic dual in line package (PDIP), die in waffle pack, die in wafer form, chip on board (COB), ceramic dual in line package (CERDIP), plastic metric quad flat pack (MQFP), thin quad flat pack (TQFP), small outline integrated circuit (SOIC), shrink small outline package (SSOP), thin small outline package (TSOP), system in package (SIP), multi chip package (MCP), wafer-level fabricated package (WFP), or wafer-level processed stack package (WSP).

The present disclosure may increase the number of memory cells by separating a plurality of plug patterns using a separation pattern.

What is claimed is:

1. A semiconductor device, comprising:
a gate stacked structure including insulating layers and conductive layers that are alternatingly stacked;
a hole extending in a vertical direction into the gate stacked structure and including a first sidewall and a second sidewall facing each other;
a first separation pattern and a second separation pattern that contact a boundary portion between the first sidewall and the second sidewall, the first and second separation patterns facing each other and extending in the vertical direction;
a first plug pattern contacting the first sidewall and extending in the vertical direction; and
a second plug pattern contacting the second sidewall and extending in the vertical direction.

2. The semiconductor device according to claim 1, wherein:
the first plug pattern comprises:
a first blocking insulating layer contacting the first sidewall;
a first charge trap layer contacting an inner wall of the first blocking insulating layer;
a first tunnel insulating layer contacting an inner wall of the first charge trap layer; and
a first channel layer contacting an inner wall of the first tunnel insulating layer, and
the second plug pattern comprises:
a second blocking insulating layer contacting the second sidewall;
a second charge trap layer contacting an inner wall of the second blocking insulating layer;
a second tunnel insulating layer contacting an inner wall of the second charge trap layer; and
a second channel layer contacting an inner wall of the second tunnel insulating layer.

3. The semiconductor device according to claim 2, wherein the first blocking insulating layer and the second blocking insulating layer are coupled to each other along sidewalls of the first separation pattern and the second separation pattern.

4. The semiconductor device according to claim 2, wherein the first charge trap layer and the second charge trap layer are spaced apart from each other by the first separation pattern and the second separation pattern.

5. The semiconductor device according to claim 2, wherein the first channel layer and the second channel layer are spaced apart from each other by the first separation pattern and the second separation pattern.

6. The semiconductor device according to claim 1, wherein the first plug pattern and the second plug pattern have symmetrical structures with respect to a first horizontal direction, which is orthogonal to the vertical direction.

7. The semiconductor device according to claim 6, wherein the first separation pattern and the second separation pattern have symmetrical structures with respect to a second horizontal direction, which is orthogonal to the vertical direction and the first horizontal direction.

8. The semiconductor device according to claim 1, wherein each of the first separation pattern and the second separation pattern includes a first curved surface that is convex in relation to outside the hole and a second curved surface that is concave in relation to a center of the hole.

9. The semiconductor device according to claim 1, wherein each of the first separation pattern and the second separation pattern includes a first curved surface that is convex in relation to outside the hole and a second curved surface that is convex in relation to a center of the hole.

10. The semiconductor device according to claim 1, wherein a horizontal cross-section of each of the first separation pattern and the second separation pattern has a crescent shape.

11. A method of manufacturing a semiconductor device, comprising:
forming a hole passing through at least a portion of a stacked structure, the stacked structure including first material layers and second material layers that are alternatingly stacked;
forming a first separation pattern and a second separation pattern that contact a boundary between a first sidewall and a second sidewall of the hole, the first sidewall and the first separation pattern facing the second sidewall and the second separation pattern, respectively, and the first and second sidewalls and the first and second separation patterns extending in a vertical direction;
forming a blocking insulating layer contacting the first sidewall and the second sidewall;
forming a first charge trap layer and a second charge trap layer that contact an inner wall of the blocking insulating layer, the first and second charge trap layers being spaced apart from each other by the first separation pattern and the second separation pattern;
forming a tunnel insulating layer contacting inner walls of the first charge trap layer and the second charge trap layer; and
forming a first channel layer and a second channel layer that contact an inner wall of the tunnel insulating layer, the first and second channel layers being spaced apart from each other by the first separation pattern and the second separation pattern.

12. The method according to claim 11, wherein the hole has an elliptical shape in which a width of the hole in a first horizontal direction is less than a width of the hole in a second horizontal direction, which is orthogonal to the first horizontal direction.

13. The method according to claim 12, wherein:
the first separation pattern and the second separation pattern have symmetrical structures with respect to the second horizontal direction,
the first charge trap layer and the second charge trap layer have symmetrical structures with respect to the first horizontal direction, and
the first channel layer and the second channel layer have symmetrical structures with respect to the first horizontal direction.

14. The method according to claim 12, wherein forming the first separation pattern and the second separation pattern comprises:
forming an insulating layer along a sidewall of the hole;
etching the insulating layer such that the sidewall of the hole in the first horizontal direction is exposed and allowing a portion of the insulating layer to remain on the sidewall of the hole in the second horizontal direction, thus forming the first separation pattern and the second separation pattern; and
etching the exposed sidewall of the hole and then forming both ends of each of the first separation pattern and the second separation pattern to protrude towards a center of the hole.

15. The method according to claim 14, wherein the insulating layer includes an oxide layer or a silicon oxide layer.

16. The method according to claim 14, further comprising:
performing a selective deposition process such that the first separation pattern and the second separation pattern protrude toward a center of the hole.

17. The method according to claim 11, wherein forming the first charge trap layer and the second charge trap layer comprises:
forming a charge trap layer along the inner wall of the blocking insulating layer; and
selectively removing the charge trap layer adjacent to the first separation pattern and the second separation pattern by performing an etching process and then forming the first charge trap layer and the second charge trap layer that are separated from each other.

18. The method according to claim 11, wherein forming the first channel layer and the second channel layer comprises:
forming a channel layer along the inner wall of the tunnel insulating layer; and
selectively removing the channel layer adjacent to the first separation pattern and the second separation pattern by performing an etching process and then forming the first channel layer and the second channel layer that are separated from each other.

19. A method of manufacturing a semiconductor device, comprising:
forming a hole passing through at least a portion of a stacked structure, the stacked structure including first material layers and second material layers that are alternatingly stacked;
forming a first preliminary separation pattern and a second preliminary separation pattern that contact a boundary between a first sidewall and a second sidewall of the hole, the first sidewall and the first preliminary separation pattern facing the second sidewall and the second preliminary separation pattern, respectively, and the first and second sidewalls and the first and second preliminary separation patterns extending in a vertical direction;
forming a first separation pattern and a second separation pattern from the first preliminary separation pattern and the second preliminary separation pattern, respectively, by performing an oxidization process, wherein the first separation pattern and the second separation pattern protrude toward a center of the hole;
forming a blocking insulating layer contacting the first sidewall and the second sidewall;
forming a first charge trap layer and a second charge trap layer that contact an inner wall of the blocking insulating layer, the first and second charge trap layers being spaced apart from each other by the first separation pattern and the second separation pattern;
forming a tunnel insulating layer contacting inner walls of the first charge trap layer and the second charge trap layer; and
forming a first channel layer and a second channel layer that contact an inner wall of the tunnel insulating layer, the first and second charge trap layers being spaced apart from each other by the first separation pattern and the second separation pattern.

20. The method according to claim 19, wherein the hole has an elliptical shape in which a width of the hole in a first horizontal direction is less than a width of the hole in a second horizontal direction, which is orthogonal to the first horizontal direction.

21. The method according to claim 20, wherein:
the first separation pattern and the second separation pattern have symmetrical structures with respect to the second horizontal direction,
the first charge trap layer and the second charge trap layer have symmetrical structures with respect to the first horizontal direction, and
the first channel layer and the second channel layer have symmetrical structures with respect to the first horizontal direction.

22. The method according to claim 20, wherein forming the first preliminary separation pattern and the second preliminary separation pattern comprises:
forming a sacrificial layer along a sidewall of the hole; and
etching the sacrificial layer such that the sidewall of the hole in the first horizontal direction is exposed and allowing a portion of the sacrificial layer to remain on the sidewall of the hole in the second horizontal direction, thus forming the first preliminary separation pattern and the second preliminary separation pattern.

23. The method according to claim 22, further comprising:
performing a selective deposition process such that the first preliminary separation pattern and the second preliminary separation pattern protrude toward the center of the hole.

24. The method according to claim 22, wherein the sacrificial layer includes a polysilicon layer.

25. The method according to claim 19, wherein forming the first charge trap layer and the second charge trap layer comprises:
forming a charge trap layer along the inner wall of the blocking insulating layer; and
selectively removing the charge trap layer adjacent to the first separation pattern and the second separation pattern by performing an etching process and then forming the first charge trap layer and the second charge trap layer that are separated from each other.

26. The method according to claim 19, wherein forming the first channel layer and the second channel layer comprises:
forming a channel layer along the inner wall of the tunnel insulating layer; and
selectively removing the channel layer adjacent to the first separation pattern and the second separation pattern by performing an etching process and then forming the first channel layer and the second channel layer that are separated from each other.
